(19) United States
(12) Patent Application Publication
(10) Pub. No.: US 2021/0172978 A1
(43) Pub. Date: Jun. 10, 2021

(54) CUSTOMIZABLE PROBE CARDS, PROBE SYSTEMS INCLUDING THE SAME, AND RELATED METHODS

(71) Applicant: FormFactor Beaverton, Inc., Beaverton, OR (US)

(72) Inventors: Yoichi Funatoko, Tokyo (JP); Nobuhiro Kawamata, Ibaraki (JP); Masahiro Sameshima, Tokyo (JP); Masanori Watanabe, Tokyo (JP)

(21) Appl. No.: 17/090,715

(22) Filed: Nov. 5, 2020

Related U.S. Application Data
(60) Provisional application No. 62/945,718, filed on Dec. 9, 2019.

(51) Int. Cl. G01R 1/073; G01R 1/04

(52) U.S. Cl. CPC G01R 1/07392; G01R 1/07342; G01R 1/0408

(57) ABSTRACT

Customizable probe cards, probe systems including the same, and related methods. A customizable probe card for testing one or more devices under test (DUTs) comprises a support structure, one or more probe assemblies supporting respective probes, and a probe repositioning assembly. The probe repositioning assembly is configured to facilitate selective adjustment of an orientation of at least one probe relative to the support structure. In examples, a probe system comprises a chuck for supporting a substrate that includes one or more DUTs, a customizable probe card, and a probe card holder. In examples, methods of reconfiguring a customizable probe card comprise utilizing a probe repositioning assembly to reposition the respective probe of at least one probe assembly.

### RELATED APPLICATION

This application claims priority to U.S. Provisional Patent Application No. 62/945,718, which is entitled CUSTOMIZABLE PROBE CARDS, PROBE SYSTEMS INCLUDING THE SAME, AND RELATED METHODS, was filed on Dec. 9, 2019, and the complete disclosure of which is hereby incorporated by reference.

### FIELD OF THE DISCLOSURE

The present disclosure relates generally to probe cards for probe systems and more specifically to customizable probe cards with probes configured to be selectively repositioned on the customizable probe cards.

### BACKGROUND OF THE DISCLOSURE

Probe systems may be utilized to test the operation of a device under test (DUT). In specific examples, the DUT may include a semiconductor device, and the probe system may be configured to electrically test the operation of the DUT, such as by providing a test signal to the DUT and/or by receiving a resultant signal from the DUT.

In some configurations, the probe systems utilize a probe card that includes one or more probes for testing the DUT, with the probe card being configured to be selectively and repeatedly installed on and removed from a probe card holder of the probe system. In this manner, the probe systems may be reconfigured for testing differently configured DUTs by selectively installing a probe card with probes that are specifically configured and/or arranged for testing a given DUT. However, replacing the probe cards in this manner may incur undesired downtime and/or monetary expenses. In addition, each probe card may be custom-made for a given DUT, thereby increasing operational costs and/or lead time associated with designing, manufacturing, and/or obtaining an appropriate probe card for a given DUT. Thus, there exists a need for customizable probe cards.

### SUMMARY OF THE DISCLOSURE

Customizable probe cards, probe systems including the same, and related methods are disclosed herein. A customizable probe card for testing one or more devices under test (DUTs) includes a support structure, one or more probe assemblies supporting respective probes and operatively coupled to the support structure, and a probe repositioning assembly. The probe repositioning assembly is configured to facilitate selective adjustment of an orientation of the respective probe of at least one probe assembly of the one or more probe assemblies relative to the support structure. The customizable probe card is configured to be selectively reconfigured for operative use with each of a plurality of distinct DUTs by selectively repositioning the respective probe of at least one probe assembly of the one or more probe assemblies relative to the support structure.

In some examples, a probe system comprises a chuck with a chuck support surface configured to support a substrate that includes one or more DUTs, a customizable probe card configured to test the one or more DUTs, and a probe card holder configured to support the customizable probe card relative to the substrate.

In some examples, a method of reconfiguring a customizable probe card with at least one probe assembly comprises utilizing a probe repositioning assembly to reposition a respective probe of at least one probe assembly. In some such examples, the customizable probe card is configured to be selectively reconfigured for operative use with each of a plurality of distinct DUTs by selectively repositioning the respective probe of at least one probe assembly relative to a support structure. In some such examples, each DUT includes one or more testing locations, and the respective probe of each probe assembly of the customizable probe card is configured to interface with a respective testing location of the respective DUT to test the respective DUT. In such examples, the repositioning the respective probe of the at least one probe assembly includes bringing the respective probe of each probe assembly of the at least one probe assembly to a respective orientation that corresponds to a configuration of one of the one or more testing locations.

### BRIEF DESCRIPTION OF THE DRAWINGS

FIG. 1 is a schematic illustration of examples of probe systems including customizable probe cards according to the present disclosure.

FIG. 2 is a schematic top plan view illustrating examples of repositioning probes of customizable probe cards according to the present disclosure.

FIG. 3 is a top side isometric view of an example of a customizable probe card according to the present disclosure.

FIG. 4 is a top side isometric view of a probe assembly of the customizable probe card of FIG. 3.

FIG. 5 is an exploded top side isometric view of a probe holder and a probe of the probe assembly of FIG. 4.

FIG. 6 is an exploded top side isometric view of the probe assembly of FIG. 4.

FIG. 7 is a top side perspective view of an example of a probe engaging a testing location according to the present disclosure.

FIG. 8 is a top side perspective view of another example of a customizable probe card according to the present disclosure.

FIG. 9 is a top side isometric view of an example of a customizable probe card that includes a magnetic plate according to the present disclosure.

FIG. 10 is a top side perspective view of another example of a customizable probe card that includes a magnetic plate according to the present disclosure.

FIG. 11 is a top side perspective view of an example of a customizable probe card that includes a plurality of magnetic plates according to the present disclosure.

FIG. 12 is a schematic illustration of an example of a user interface according to the present disclosure.

FIG. 13 is a schematic illustration of another example of a user interface according to the present disclosure.

FIG. 14 is a flowchart depicting examples of methods of reconfiguring a customizable probe card according to the present disclosure.

### DETAILED DESCRIPTION AND BEST MODE OF THE DISCLOSURE

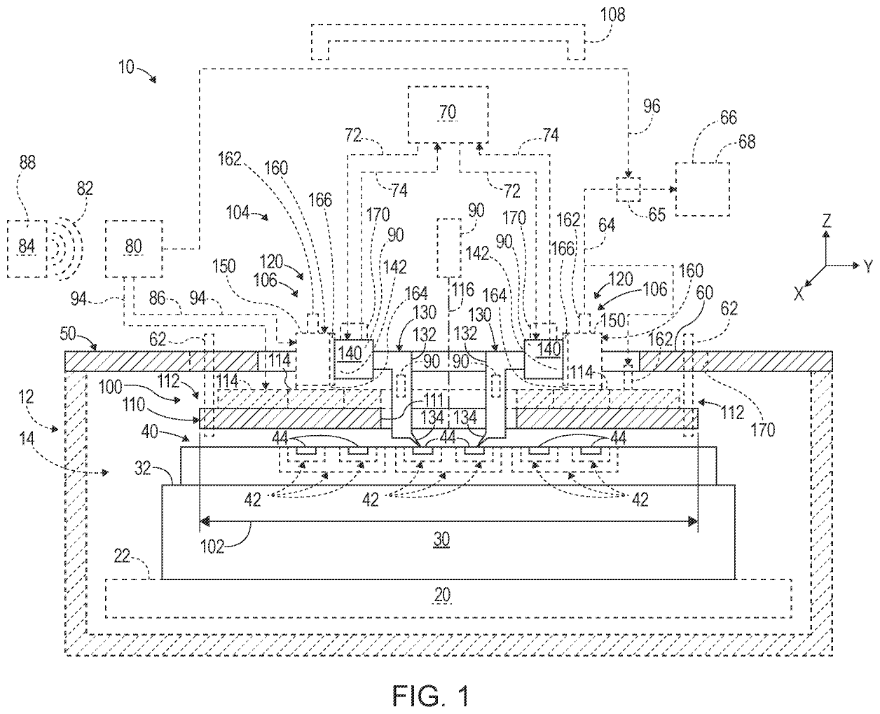

FIGS. 1-13 provide examples of customizable probe cards 100, of probe systems 10 that include customizable probe cards 100, and/or of methods 200 of reconfiguring customizable probe cards 100, according to the present disclosure. Elements that serve a similar, or at least substantially similar, purpose are labeled with like numbers in FIGS. 1-13, and these elements may not be discussed in detail herein with reference to each of FIGS. 1-13. Similarly, all elements may not be labeled in FIGS. 1-13, but reference numbers associated therewith may be utilized herein for consistency. Elements, components, and/or features that are discussed herein with reference to any of FIGS. 1-13 also may be included in and/or utilized with the subject matter of any other of FIGS. 1-13 without departing from the scope of the present disclosure. In general, elements that are likely to be included in a particular embodiment are illustrated in solid lines, while elements that are optional are illustrated in dashed lines. However, elements that are shown in solid lines may not be essential and, in some embodiments, may be omitted without departing from the scope of the present disclosure.

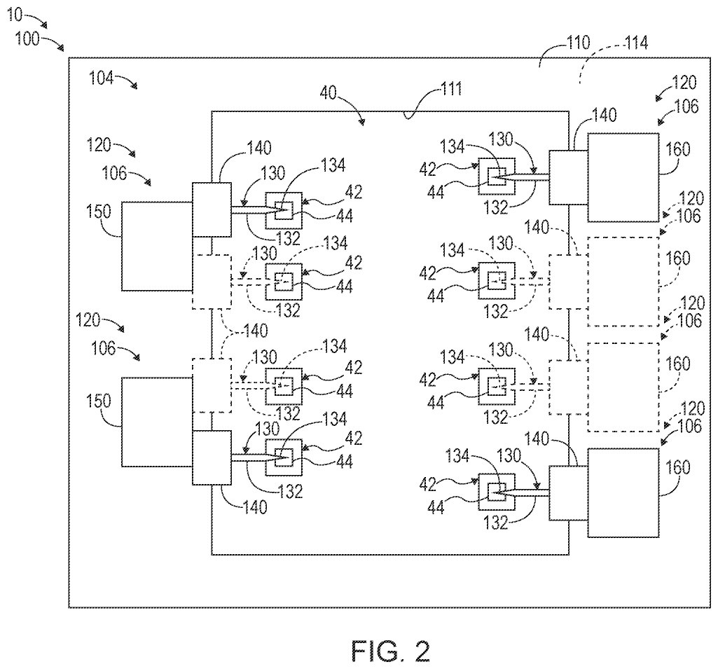

FIGS. 1-2 schematically illustrate examples of probe systems 10 and/or of customizable probe cards 100 according to the present disclosure. Specifically, FIG. 1 is a schematic side view of examples of probe systems 10 including examples of customizable probe cards 100, while FIG. 2 is a schematic top view representing aspects of the functionality of customizable probe cards 100, as described herein. As schematically illustrated in FIGS. 1-2, probe systems 10 and/or customizable probe cards 100 may be adapted, configured, designed, shaped, sized, and/or constructed to test one or more devices under test (DUTs) 42, which may be formed on, supported by, and/or included in a substrate 40. Specifically, and as schematically illustrated in FIGS. 1-2, probe systems 10 are configured such that customizable probe card 100 is positioned relative to DUT(s) 42 in a manner that facilitates testing the DUT(s) with one or more probes 130 of the customizable probe card.

Substrate 40 may include and/or be any suitable structure that may support, include, and/or have formed thereon DUT 42. Examples of substrate 40 include a wafer, a semiconductor wafer, a silicon wafer, a gallium nitride wafer, and/or a gallium arsenide wafer. Similarly, DUT 42 may include and/or be any suitable structure that may be probed and/or tested by probe system 10. As examples, DUT 42 may include a semiconductor device, an electronic device, an optical device, an optoelectronic device, a logic device, a power device, a switching device, and/or a transistor.

Conventional probe systems may utilize a conventional probe card that includes one or more probes for testing one or more corresponding DUTs. Such conventional probe cards generally are configured such that a spatial orientation and/or configuration of the probe(s) attached thereto is fixed and corresponds to a spatial orientation and/or configuration of the corresponding DUT(s) formed on the substrate. However, such probe cards may require replacement in order for the corresponding probe system to be utilized to test substrates and/or DUTs that are differently configured.

To mitigate such inefficiency and/or expense, customizable probe cards 100 according to the present disclosure are configured to facilitate reconfiguration of probes 130 such that the customizable probe card may be utilized with any of a plurality of differently configured substrates and/or DUTs. For example, and as discussed in more detail herein, FIG. 2 schematically illustrates an example of customizable probe card 100 in which each probe 130 is configured to be selectively relocated between at least a first position (schematically illustrated in solid lines) and a second position (schematically illustrated in dashed lines), with the probes being aligned with distinct sets of DUTs 42 in the first position and in the second position. In this manner, customizable probe card 100 may be selectively customized, adjusted, and/or reconfigured to modify a configuration, an orientation, a layout, etc. of the probes in order to test corresponding DUTs 42 with distinct spatial distributions and/or configurations. As used herein, customizable probe card 100 also may be referred to as an adjustable probe card 100, a reconfigurable probe card 100, and/or a customized probe card 100.

As schematically illustrated in FIGS. 1-2, a customizable probe card 100 includes a support structure 110, one or more probe assemblies 120 operatively coupled to and/or supported by the support structure, and a probe repositioning assembly 104. More specifically, and as schematically illustrated in FIGS. 1-2, each probe assembly 120 includes a respective probe 130. In some examples, and as schematically illustrated in FIGS. 1-2, each probe assembly 120 includes a respective probe holder 140 that engages, holds, and/or supports the respective probe. Each probe holder 140 may support the respective probe 130 in any of a variety of manners such that the respective probe may be operatively positioned to test the corresponding DUT 42.

In some examples, and as schematically illustrated in FIGS. 1-2, support structure 110 defines an aperture 111, and at least a portion of at least one probe assembly 120 extends through the aperture to interface with a corresponding DUT 42. As a more specific example, and as schematically illustrated in FIGS. 1-2, at least one probe assembly 120 may be configured such that the respective probe holder 140 and/or the respective probe 130 extends through aperture 111 during operative use of customizable probe card 100. In this manner, and as schematically illustrated in FIGS. 1-2, each probe assembly 120 may be operatively coupled to and/or supported by an upper side of support structure 110, with each probe 130 being positioned to test a corresponding DUT 42 of substrate 40 that is positioned below the support structure. Support structure 110 may include and/or be any suitable structure for supporting each probe assembly 120 relative to substrate 40, examples of which include a surface that is at least substantially flat, a surface that is at least substantially planar, a plate, a rigid plate, an electrically conductive plate, an electrically insulating plate, an at least partially dielectric plate, and/or an at least partially metallic plate. Additionally or alternatively, in some examples, and as schematically illustrated in FIG. 1, customizable probe card 100 defines a normal axis 116 such that support structure 110 extends at least substantially perpendicular to the normal axis. Stated differently, support structure 110 may be described as extending within a plane that is at least substantially perpendicular to normal axis 116.

As used herein, the terms “operative use,” “operatively utilized,” and the like, as used to describe a configuration in which probe system 10 and/or customizable probe card 100 operates to test substrate 40 and/or DUT(s) 42, generally relate to examples in which the probe system supports the substrate and the customizable probe card is operable to test at least one DUT on the substrate. For example, probe system 10 and/or customizable probe card 100 may be described as being in operative use when at least one probe 130 of the customizable probe card is positioned to engage and/or interface with a respective testing location 44 for testing a corresponding DUT 42, is configured to provide test signal 72 to the testing location, and/or is configured to receive resultant signal 74 from the testing location. However, such descriptions are not limiting with respect to the structures and components described herein, and it is to be understood that the structures and components disclosed herein do not require that customizable probe card 100 always be in operative use and/or operatively positioned relative to substrate 40 and/or DUT(s) 42.

Each probe 130 may have any appropriate form and/or structure for testing DUT 42. In particular, and as schematically illustrated in FIGS. 1-2, each DUT 42 may include one or more testing locations 44 such that the respective probe 130 of each probe assembly 120 of customizable probe card 100 is configured to interface with a respective testing location 44 to test DUT 42. In some examples, such as in the example of FIG. 2, each DUT 42 includes a single respective testing location 44, such that each probe assembly 120 of customizable probe card 100 is configured to test a corresponding DUT 42. In other examples, and as schematically illustrated in FIG. 1, at least one DUT 42 of substrate 40 includes a plurality of respective testing locations 44. In all such examples, utilizing customizable probe card 100 to test each DUT 42 may require that each probe 130 be aligned with the respective testing location 44. Accordingly, and as discussed in more detail herein, customizable probe cards 100 according to the present disclosure are configured to facilitate selective repositioning and/or reconfiguration of probes 130 relative to support structure 110 and/or relative to one another, thereby enabling customizable probe card 100 to test DUTs 42 with distinct configurations. As used herein, the term “aligned,” as used to describe a relative orientation of a probe 130 (and/or a portion thereof) and a corresponding DUT 42 (and/or a portion thereof), generally refers to a configuration in which the probe is at least substantially vertically aligned with the corresponding DUT, at least substantially horizontally aligned with the corresponding DUT, at least substantially aligned with a corresponding testing location 44 of the corresponding DUT, and/or positioned such that a corresponding probe 130 contacts the corresponding testing location.

As used herein, directional terms such as “horizontal,” “vertical,” and the like generally refer to a configuration in which substrate 40 extends at least substantially parallel to the ground and in which customizable probe card 100 is positioned vertically above the substrate. Similarly, as used herein, positional terms such as “above,” “over,” “below,” “underneath,” and the like generally refer to relative positions along a vertical direction, such as along the Z-direction that is illustrated in FIG. 1. For example, FIG. 1 may be described as schematically illustrating a configuration in which each probe 130 is positioned above substrate 40. However, such configurations are not required, and it is additionally within the scope of the present disclosure that customizable probe card 100 may have any suitable orientation relative to substrate 40 and/or relative to the ground.

Customizable probe card 100 may be configured to interface with testing locations 44 in any of a variety of forms. As examples, each testing location 44 may include and/or be a contact pad, a solder bump, an optical coupler, etc. In some examples, each probe 130 has a form corresponding to a form of each testing location 44. As an example, probe 130 may be a vertical probe, such as may be configured to contact a respective testing location 44 in the form of a solder bump of a corresponding DUT 42. As another example, and as schematically illustrated in FIG. 1, probe 130 may be a cantilever probe that is configured to contact a respective testing location 44 in the form of a contact pad 44 of a corresponding DUT 42. In other examples, the respective probe 130 and/or the respective probe tip 134 of at least one probe assembly 120 may be configured for non-contact testing of DUT 42. For example, at least one probe 130 may be an optical probe and/or a probe antenna, such as a probe that is configured to be optically and/or electromagnetically coupled to testing location 44 for non-contact testing of DUT 42.

In some examples, and as schematically illustrated in FIGS. 1-2, the respective probe 130 of at least one probe assembly 120 includes a respective probe body 132 that is operatively coupled to the respective probe holder 140 and a respective probe tip 134 configured to test DUT 42. Stated differently, in such examples, probe tip 134 is configured to interface with testing location 44 to test DUT 42. In some such examples, probe body 132 is configured to be selectively and repeatedly operatively coupled to and uncoupled from the respective probe holder 140, such as to permit replacement of probe 130 if the probe becomes damaged and/or otherwise unsuitable for testing DUT 42. In some such examples, probe body 132 and/or probe tip 134 includes and/or is a microelectromechanical system (MEMS) device. In some examples, probe body 132 additionally or alternatively may be referred to as a probe blade 132.

As schematically illustrated in FIG. 1, each probe 130 and/or the respective probe tip 134 may be configured to provide a corresponding test signal 72 to DUT 42 and/or to receive a corresponding resultant signal 74 from DUT 42. Test signal 72 may include and/or be a direct current test signal, an alternating current test signal, an analog test signal, and/or a digital test signal. In some examples, and as schematically illustrated in FIG. 1, probe system 10 additionally includes a signal generation and analysis assembly 70 that may be configured to provide each test signal 72 to probe assembly 120 and/or to receive each resultant signal 74 from probe assembly 120.

As described in more detail herein, probe repositioning assembly 104 is configured to facilitate selective adjustment of a relative position and/or orientation of the respective probe 130 of at least one probe assembly 120 relative to support structure 110. In this manner, customizable probe card 100 may be selectively reconfigured for operative use with distinct substrates 40 and/or distinct DUTs 42 by selectively repositioning the respective probe 130 of at least one probe assembly 120 relative to support structure 110. Stated differently, customizable probe card 100 may be configured to be utilized to test DUTs 42 (e.g., individual DUTs 42 and/or substrates 40 including corresponding pluralities of DUTs 42) with corresponding testing locations 44 that differ in position and/or orientation (e.g., with respect to support structure 110) by selectively repositioning one or more probes 130 to conform to the configuration of testing locations 44. In this manner, customizable probe card 100 may be selectively configured and utilized to test DUTs with any of a plurality of distinct forms and/or distributions of testing locations 44 without necessitating a corresponding plurality of distinct conventional probe cards.

As described in more detail herein, probe repositioning assembly 104 may form a portion of, and/or be at least partially defined by, each probe assembly 120. As a more specific example, and as schematically illustrated in FIGS. 1-2, at least one probe assembly 120 may include a respective probe repositioning mechanism 106, such that probe repositioning assembly 104 of customizable probe card 100 includes and/or is the collection of the respective probe repositioning mechanism(s) 106 of probe assembly(ies) 120.

As schematically illustrated in FIGS. 1-2, each probe assembly 120 and/or the respective probe holder 140 thereof may be operatively coupled to and/or supported by support structure 110 and thus may support the respective probe 130 relative to support structure 110. In this manner, probe holder 140 may include and/or be any appropriate structure that at least partially engages, holds, and/or supports probe 130 in position relative to support structure 110. As examples, probe holder 140 may include and/or be a clamp, a slot, a fixture, a socket, etc. for retaining probe 130.

In various examples, and as described in more detail herein, probe repositioning assembly 104 and/or the respective probe repositioning mechanism 106 of at least one probe assembly 120 is configured to facilitate selectively repositioning at least one probe assembly 120 and/or the respective probe holder 140 thereof relative to support structure 110 to selectively reposition the respective probe(s) 130 relative to the support structure. In some examples, and as schematically illustrated in FIGS. 1-2, probe repositioning assembly 104, at least one probe assembly 120, and/or the respective probe repositioning mechanism 106 thereof includes a probe translation stage 150 that operatively supports the respective probe holder 140 and/or the respective probe 130 of the probe assembly relative to support structure 110 and that is configured to selectively reposition the respective probe holder relative to the support structure. Stated differently, in such examples, and as schematically illustrated in FIG. 2, probe translation stage 150 may be fixedly coupled to support structure 110 during adjustment of the respective probe 130 relative to support structure 110, and the probe translation stage may be configured to move the respective probe holder 140 and/or the respective probe 130 relative to the support structure through a probe range of motion associated with the probe translation stage to configure customizable probe card 100 for a particular configuration of testing locations 44. More specifically, FIG. 2 schematically illustrates an example in which probe repositioning assembly 104 includes a pair of probe translation stages 150, each of which supports a respective probe holder 140. In the example of FIG. 2, each probe translation stage operates to reposition the probe holder relative to support structure 110 between the first position schematically illustrated in solid lines and the second position schematically illustrated in dashed lines (and/or to any other position between the first position and the second position). In some examples, the respective probe holder 140 of at least one probe assembly 120 may be directly coupled to and/or supported by the respective probe translation stage 150. In some such examples, the respective probe translation stage 150 may be described as including and/or defining the respective probe holder 140.

In some examples, the respective probe holder 140 and/or the respective probe translation stage 150 of at least one probe assembly 120 are configured to be selectively removed from support structure 110. As a more specific example, the respective probe translation stage 150 of at least one probe assembly 120 may be configured to be selectively and repeatedly operatively coupled to and uncoupled from support structure 110 without damage to the respective probe translation stage. Additionally or alternatively, the respective probe holder 140 and/or the respective probe translation stage 150 of at least one probe assembly 120 may be configured such that the respective probe holder may be selectively and repeatedly operatively coupled to and uncoupled from the respective probe translation stage.

Each probe translation stage 150 may be configured to move the respective probe holder 140 and/or the respective probe 130 relative to support structure 110 in any of a variety of manners, such as by selectively translating and/or selectively rotating the respective probe holder and/or the respective probe relative to support structure 110. As examples, each probe translation stage 150 may be configured to translate the respective probe holder 140 and/or the respective probe 130 relative to support structure 110 along one or more linear dimensions. More specifically, such linear dimensions may include one or more linear dimensions that extend at least substantially parallel to normal axis 116 and/or one or more linear dimensions that extend at least substantially perpendicular to the normal axis. Additionally or alternatively, each probe translation stage 150 may be configured to rotate the respective probe holder and/or the respective probe relative to the support structure 110, such as about an axis that is at least substantially parallel to normal axis 116 and/or about an axis that is at least substantially perpendicular to the normal axis. In this manner, each probe translation stage 150 may be utilized to operatively translate the respective probe 130 throughout the probe range of motion, thereby operatively translating each probe relative to substrate 40 and/or DUT(s) 42. In some examples, the respective probe translation stages 150 of each probe assembly 120 collectively may be utilized to operatively align the respective probes 130 with specific, target, and/or desired testing locations 44 on substrate 40 and/or on DUT 42, such as to permit communication between the respective probes and the substrate and/or DUT. This may include operative translation of each respective probe 130 in a plurality of different, separate, distinct, perpendicular, and/or orthogonal directions, such as the X-, Y-, and/or Z-directions that are illustrated in FIG. 1. Additionally or alternatively, this may include operative rotation of each respective probe 130 about one or more axes, such as axes that are at least substantially parallel with one or more of the X-, Y-, and/or Z-directions that are illustrated in FIG. 1. In the example of FIG. 1, the X- and Y-directions may be parallel, or at least substantially parallel, to substrate 40, while the Z-direction may be perpendicular, or at least substantially perpendicular, to substrate 40. However, this specific configuration is not required.

Each probe translation stage 150 may include and/or be any suitable structure that may be operatively attached to the respective probe holder 140 and/or the respective probe 130, and/or that may be configured to operatively translate and/or rotate the respective probe 130 throughout the probe range-of-motion, such as may extend in three orthogonal, or at least substantially orthogonal, axes, such as the X-, Y-, and Z-axes of FIG. 1. As examples, each probe translation stage 150 may include one or more translation stages, lead screws, ball screws, rack and pinion assemblies, motors, stepper motors, electrical actuators, mechanical actuators, piezoelectric actuators, micrometers, and/or manual actuators.

In some examples, the respective probe translation stage 150 of at least one probe assembly 120 may include and/or be a manually actuated stage, such as a stage that is configured to move the respective probe 130 via manual adjustment of one or more actuators. Additionally or alternatively, the respective probe translation stage 150 of at least one probe assembly 120 may include and/or be a motorized, automated, or electrically actuated stage.

In an example in which probe translation stage 150 is a motorized stage, the probe translation stage may be controlled in any of a variety of manners. For example, and as schematically illustrated in FIG. 1, probe system 10 may include a controller 80 that is configured to at least partially control the operation of probe system 10. In some examples, and as schematically illustrated in FIG. 1, controller 80 may be configured to transmit a stage control signal 86 to the respective probe translation stage 150 of at least one probe assembly 120, such as via a wired connection.

In some such examples, and as schematically illustrated in FIG. 1, controller 80 is a network-connected device that is configured to receive a wireless control signal 82 from a user interface device 84 such that stage control signal 86 is at least partially based upon the wireless control signal. In such examples, controller 80 and/or user interface device 84 each may include and/or be any of a plurality of suitable devices and/or interfaces, examples of which include a computer, a software program, a Web site, a mobile phone, and an Internet-connected device. For example, and as schematically illustrated in FIG. 1, user interface device 84 may be a device that is configured to provide a user with a user interface 88 for receiving an input corresponding to a desired adjustment of the respective probe translation stage 150 of at least one probe assembly 120. As more specific examples, user interface 88 may enable the user to specify a target destination of at least one probe 130 (e.g., relative to support structure 110 and/or substrate 40), a desired translation and/or rotation of at least one probe by the respective probe translation stage 150, a desired relative orientation between a given probe assembly 120 and support structure 110, etc.

In some examples, controller 80 may be associated with, and/or a component of, signal generation and analysis assembly 70 of probe system 10. That is, while FIG. 1 schematically illustrates signal generation and analysis assembly 70 and controller 80 as being distinct devices, this is not required. For example, it is additionally within the scope of the present disclosure that signal generation and analysis assembly 70 and controller 80 may be a common device, and/or may refer to respective portions and/or functions of a common device.

Signal generation and analysis assembly 70 and/or controller 80 each may be any suitable device or devices that are configured to perform the functions of the controller discussed herein. For example, the signal generation and analysis assembly and/or the controller each may include one or more of an electronic controller, a dedicated controller, a special-purpose controller, a personal computer, a special-purpose computer, a display device, a logic device, a memory device, and/or a memory device having non-transitory computer readable media suitable for storing computer-executable instructions for implementing aspects of systems and/or methods according to the present disclosure.

Additionally or alternatively, signal generation and analysis assembly 70 and/or controller 80 each may include, or be configured to read, non-transitory computer readable storage, or memory, media suitable for storing computer-executable instructions, or software, for implementing methods or steps of methods according to the present disclosure. Examples of such media include CD-ROMs, disks, hard drives, flash memory, etc. As used herein, storage, or memory, devices and media having computer-executable instructions as well as computer-implemented methods and other methods according to the present disclosure are considered to be within the scope of subject matter deemed patentable in accordance with Section 101 of Title 35 of the United States Code.

Signal generation and analysis assembly 70 additionally or alternatively may include and/or be any suitable structure that may, or that may be configured to, generate test signal 72, transmit test signal 72, receive resultant signal 74, and/or analyze resultant signal 74. Examples of signal generation and analysis assembly 70 include a signal generator, an electric signal generator, an optical signal generator, a wireless signal generator, an electromagnetic signal generator, a signal detector, an electric signal detector, an optical signal detector, a wireless signal detector, and/or an electromagnetic signal detector.

While the foregoing discussion generally relates to examples in which each probe 130 is repositionable within a range of motion of the respective probe translation stages 150, it is additionally within the scope of the present disclosure that each probe 130 may be selectively repositioned independent of a probe translation stage and/or beyond a range of motion thereof. For example, customizable probe card 100 may be configured such that the respective probe 130 of at least one probe assembly 120 may be selectively repositioned relative to support structure 110 via selective placement of the associated probe assembly 120 and/or the respective probe holder 140 thereof relative to support structure 110, such as by selectively repositioning a location at which the probe assembly and/or the respective probe holder is operatively coupled to and/or supported by the support structure. As a more specific example, and as schematically illustrated in FIGS. 1-2, at least one probe assembly 120 may include a respective probe assembly mounting structure 160 that is configured to be operatively coupled to support structure 110 to selectively and operatively couple and/or retain the probe assembly to the support structure at a selected location on and/or relative to the support structure. Stated differently, in such examples, the respective probe assembly mounting structure 160 of each probe assembly 120 may be configured to selectively and operatively couple the probe assembly and/or the respective probe holder 140 to (and/or relative to) support structure 110 at any of a plurality of distinct locations on the support structure. That is, in such examples, probe assembly mounting structure 160 may be configured to be operatively coupled to support structure 110 at any of a plurality of distinct selected locations and/or orientations relative to the support structure in order to reposition the respective probe assembly 120 and/or the respective probe holder 140 relative to the support structure. In some examples, the plurality of distinct selected locations and/or orientations includes and/or is a continuous plurality and/or distribution of selected locations and/or orientations. Stated differently, in such examples, probe assembly mounting structure 160 may be configured such that the location and/or orientation of the respective probe assembly 120 relative to support structure 110 is continuously variable and/or infinitely variable. Stated yet another way, probe assembly mounting structure 160 may be configured to be coupled to support structure 110 at any location and/or with any orientation within a continuous range of locations and/or orientations. In some examples, and as described herein, the respective probe assembly mounting structure 160 also is configured to selectively and operatively uncouple the probe assembly from the support structure, such as to facilitate repositioning probe assembly 120 relative to the support structure.

In some examples, probe repositioning assembly 104 may be described as including and/or being the respective probe assembly mounting structure 160 of each probe assembly 120. Similarly, in some examples, the respective probe repositioning mechanism 106 of each probe assembly 120 may include and/or be the respective probe assembly mounting structure 160 of the probe assembly.

FIG. 2 schematically illustrates an example in which probe repositioning assembly 104 includes a pair of probe assembly mounting structures 160, each of which supports a respective probe holder 140. In the example of FIG. 2, each probe assembly mounting structure 160 may be selectively coupled to and uncoupled from support structure 110, such as to move each probe assembly mounting structure (and/or the corresponding probe assembly 120) between a first position, schematically illustrated in solid lines, and a second position, schematically illustrated in dashed lines, for testing DUTs 42 and/or testing locations 44 with distinct locations and/or configurations. In this manner, in such examples, each probe assembly 120 and/or the respective probe holder 140 generally is configured to be selectively moved relative to support structure 110 while reconfiguring customizable probe card 100, and to be selectively fixed (or at least substantially fixed) in position relative to support structure 110 during operative use of the customizable probe card to test DUT(s) 42. In some such examples, the respective probe assembly mounting structure 160 of at least one probe assembly 120 may operatively support and/or include the respective probe translation stage 150 of the probe assembly.

While FIG. 1 schematically illustrates each probe holder 140 as being operatively coupled to support structure 110 via probe translation stage 150 or via probe assembly mounting structure 160 (i.e., via a structure that is distinct from the probe holder), this is not required. For example, it is additionally within the scope of the present disclosure that probe holder 140 may be directly coupled to support structure 110. In such examples, probe holder 140 may be described as including and/or being probe assembly mounting structure 160.

Each probe assembly mounting structure 160 may be selectively and operatively retained in position relative to support structure 110 in any appropriate manner. As examples, each probe assembly mounting structure 160 may be configured to be selectively retained in position relative to support structure 110 via a magnetic force, a mechanical force, and/or a suction force, such as a suction force produced by applying a vacuum (e.g., at least substantially evacuating of air) to an interface region between the probe assembly mounting structure and the support structure.

In some examples, and as schematically illustrated in FIG. 1, probe repositioning assembly 104 includes a magnetic plate 114 such that at least one probe assembly mounting structure 160 may be selectively magnetically coupled to the magnetic plate at a selected position on the magnetic plate. For example, the respective probe assembly mounting structure 160 of at least one probe assembly 120 may include and/or be a magnetized material such as a permanent magnet and/or an electromagnet, and magnetic plate 114 may include and/or be a magnetized material and/or a ferromagnetic material. Additionally or alternatively, magnetic plate 114 may include and/or be a magnetized material such as a permanent magnet and/or an electromagnet, and the respective probe assembly mounting structure 160 of at least one probe assembly 120 may include and/or be a magnetized material and/or a ferromagnetic material. In some examples, and as schematically illustrated in FIG. 1, the respective probe assembly mounting structure 160 of at least one probe assembly 120 may include a magnetic plate coupling material 164 that is configured to magnetically couple the respective probe assembly mounting structure to magnetic plate 114. In such examples, magnetic plate coupling material 164 may include and/or be a magnetized material, a ferromagnetic material, and/or a permanent magnet.

In some examples, magnetic plate 114 is at least substantially fixed relative to support structure 110 and/or fixedly coupled to the support structure. While FIG. 1 schematically illustrates magnetic plate 114 as being distinct from support structure 110, this is not required, and it is additionally within the scope of the present disclosure that support structure 110 includes, and/or is, magnetic plate 114.

In some examples, the respective probe assembly mounting structure 160 of at least one probe assembly 120 may be configured to be selectively magnetically coupled to magnetic plate 114 via a variable magnetic force. As a more specific example, magnetic plate 114 and/or the respective probe assembly mounting structure 160 of at least one probe assembly 120 may include and/or be an electromagnet that is configured to be selectively magnetized to selectively fix the respective probe assembly mounting structure in position relative to the magnetic plate during operative use of customizable probe card 100. In such examples, the electromagnet may be selectively demagnetized to permit the respective probe assembly mounting structure to be selectively repositioned relative to the magnetic plate. In some examples, and as schematically illustrated in FIG. 1, controller 80 is configured to transmit an electromagnet control signal 94 to magnetic plate 114 and/or the respective probe assembly mounting structure 160 of at least one probe assembly 120 to at least partially control the magnetic force produced by the electromagnet. In other examples, probe assembly mounting structure 160 and magnetic plate 114 may be configured to be magnetically coupled to one another via a magnetic force that is not configured to be selectively variable. For example, one of probe assembly mounting structure 160 and magnetic plate 114 may include and/or be a permanent magnet, and the other one of the probe assembly mounting structure and the magnetic plate may be a permanent magnet or a ferromagnetic material.

In some examples, and as schematically illustrated in FIG. 1, probe repositioning assembly 104 may include a single magnetic plate 114 such that the respective probe assembly mounting structures 160 of one or more probe assemblies 120 are magnetically coupled to the single magnetic plate. In other examples, and as additionally schematically illustrated in dashed lines in FIG. 1, probe repositioning assembly 104 may include a plurality of magnetic plates 114 that are spaced apart from one another. In such examples, and as schematically illustrated in FIG. 1, the respective probe assembly mounting structures 160 of each of a plurality of probe assemblies 120 may be magnetically coupled to a respective magnetic plate 114 of the plurality of magnetic plates. In such examples, each magnetic plate 114 may be at least substantially fixed relative to support structure 110, such that selectively translating each respective probe assembly mounting structure 160 relative to the respective magnetic plate 114 operates to translate the respective probe assembly mounting structure relative to the support structure. As used herein, references to probe assembly mounting structure 160 being operatively and/or magnetically coupled to magnetic plate 114 also may be understood as describing and/or referring to examples in which the probe assembly mounting structure is operatively and/or magnetically coupled to a respective magnetic plate of a plurality of magnetic plates.

In some examples, probe assembly mounting structure 160 may be configured to be magnetically coupled to magnetic plate 114 and to be selectively moved relative to the magnetic plate by introducing a pressurized gas between the probe assembly mounting structure and the magnetic plate. More specifically, and as schematically illustrated in FIG. 1, probe system 10 may include a gas source 66 that is configured to generate a pressurized flow of a gas, such as air, as well as a gas conduit 64 extending from the gas source to convey the pressurized flow from the gas source.

As schematically illustrated in FIG. 1, at least one probe assembly mounting structure 160 may include a gas connector 162 that is configured to be fluidly connected to gas conduit 64 to receive the pressurized flow of gas and to convey the pressurized flow to an interface between the probe assembly mounting structure and magnetic plate 114. Additionally or alternatively, and as also schematically illustrated in FIG. 1, support structure 110 and/or magnetic plate 114 may include gas connector 162 configured to be fluidly connected to gas conduit 64 to receive the pressurized flow of gas and to convey the pressurized flow to the interface between probe assembly mounting structure 160 and magnetic plate 114. More specifically, in such examples, an upper surface of magnetic plate 114 may be perforated to permit the pressurized flow of gas to flow out of the magnetic plate. In this manner, selectively introducing the pressurized gas between probe assembly mounting structure 160 and magnetic plate 114 operates to reduce a friction between the probe assembly mounting structure and the magnetic plate, thereby facilitating selective repositioning of the probe assembly mounting structure relative to the magnetic plate.

In some such examples, and as schematically illustrated in FIG. 1, probe system 10 additionally includes a valve 65 for selectively regulating a flow through gas conduit 64, such as a flow of the pressurized flow of gas, such as by selectively blocking a flow through the gas conduit. For example, and as schematically illustrated in FIG. 1, controller 80 may be configured to transmit a valve control signal 96 to valve 65 to regulate the pressurized flow through the valve. In this manner, controller 80 may enable remote control of valve 65 to selectively permit the pressurized flow to reach probe assembly mounting structure 160 and/or magnetic plate 114 for selective repositioning of the probe assembly mounting structure and/or to selectively restrict the pressurized flow from reaching the probe assembly mounting structure and/or the magnetic plate during operative use of customizable probe card 100 to test DUT(s) 42.

In other examples, and as discussed, probe assembly mounting structure 160 may be configured to be selectively retained in position relative to support structure 110 via a suction force. In some such examples, and as schematically illustrated in FIG. 1, probe system 10 includes a vacuum source 68 that is configured to pull gas and/or air through a conduit such as gas conduit 64, which in turn may be operatively fluidly coupled to probe assembly mounting structure 160 via gas connector 162 of the probe assembly mounting structure. Additionally or alternatively, and as also schematically illustrated in FIG. 1, gas conduit 64 may be operatively fluidly coupled to support structure 110 and/or to magnetic plate 114 via gas connector 162 associated with the support structure and/or the magnetic plate.

Accordingly, in such examples, vacuum source 68 may be configured to selectively apply a vacuum to the interface region between probe assembly mounting structure 160 and support structure 110 (and/or between probe assembly mounting structure 160 and magnetic plate 114) by drawing air through gas conduit 64, thereby selectively retaining the probe assembly mounting structure relative to the support structure via a suction force. In such examples, valve 65 may be configured to selectively fluidly connect vacuum source 68 to probe assembly mounting structure 160, support structure 110, and/or magnetic plate 114 to selectively retain the probe assembly mounting structure relative to the support structure.

The foregoing examples generally correspond to examples in which a force (e.g., a magnetic force and/or a suction force) retaining probe assembly mounting structure 160 relative to support structure 110 and/or magnetic plate 114 may be selectively reduced, mitigated, and/or opposed to facilitate selectively repositioning the probe assembly mounting structure relative to the support structure. However, this is not required of all examples of customizable probe card 100, and it is additionally within the scope of the present disclosure that probe assembly mounting structure 160 may be configured to be selectively repositioned relative to support structure 110 without diminishing and/or counteracting a force that retains the probe assembly mounting structure relative to the support structure. For example, in an example in which probe assembly mounting structure 160 is retained in position relative to magnetic plate 114 via a magnetic force, the probe assembly mounting structure may be configured to be selectively translated relative to the magnetic plate while the probe assembly mounting structure is operatively magnetically coupled to the magnetic plate. More specifically, in such examples, the magnitude of the attractive magnetic force that retains the probe assembly mounting structure against the magnetic plate may be sufficiently strong to retain the probe assembly mounting structure in a static position during operative use of customizable probe card 100. In such examples, the magnitude of the attractive magnetic force also may be sufficiently weak to enable the probe assembly mounting structure to be selectively translated relative to the magnetic plate, such as along a surface of the magnetic plate, along a surface of support structure 110, and/or along a direction at least substantially perpendicular to normal axis 116, while the probe assembly mounting structure remains operatively magnetically coupled to the magnetic plate.

The foregoing examples generally correspond to examples in which probe assembly mounting structure 160 enables selectively repositioning the respective probe 130 and/or the respective probe holder 140 relative to support structure 110 along a direction at least substantially perpendicular to normal axis 116, such as by moving the probe assembly mounting structure 160 along a surface of the support structure and/or of magnetic plate 114. In some examples, probe assembly mounting structure 160 additionally or alternatively may be configured to enable repositioning the respective probe 130 and/or the respective probe holder 140 relative to support structure 110 along a direction at least substantially parallel to normal axis 116, such as by selectively translating the respective probe holder relative to the probe assembly mounting structure. As a more specific example, the respective probe holder 140 of at least one probe assembly 120 may be operatively coupled to the respective probe assembly mounting structure 160 at least partially via a magnetic force in a manner that enables and/or facilitates selectively translating the respective probe holder relative to the respective probe assembly mounting structure. In some such examples, one or both of the respective probe holder 140 and the respective probe assembly mounting structure 160 includes and/or is a magnetized material, a ferromagnetic material, and/or a permanent magnet.

As a more specific example, and as schematically illustrated in FIG. 1, probe holder 140 may include mounting structure coupling material 142 that is configured to magnetically couple the probe holder to the respective probe assembly mounting structure 160. Additionally or alternatively, and as schematically illustrated in FIG. 1, probe assembly mounting structure 160 may include a probe holder coupling material 166 that is configured to magnetically couple the probe assembly mounting structure to the respective probe holder 140. In such examples, each of mounting structure coupling material 142 and/or probe holder coupling material 166 may include and/or be a magnetized material, a ferromagnetic material, and/or a permanent magnet. In such examples, probe holder 140 may be configured to be selectively translated relative to the respective probe assembly mounting structure 160 along a direction at least substantially parallel to normal axis 116 while the probe holder is operatively magnetically coupled to the respective probe assembly mounting structure 160.

In an example in which probe repositioning assembly 104 includes probe assembly mounting structure(s) 160, each probe assembly mounting structure may be selectively positioned upon support structure 110, and/or repositioned relative to the support structure, in any appropriate manner. As an example, the respective probe assembly mounting structure 160 of at least one probe assembly 120 may be configured to be manually repositioned relative to support structure 110.

Additionally or alternatively, in some examples, and as schematically illustrated in FIG. 1, probe system 10 and/or probe repositioning assembly 104 may include a repositioning jig 108 that is configured to facilitate repositioning each probe assembly mounting structure 160 and/or to facilitate alignment of each respective probe holder 140 at a predetermined orientation relative to support structure 110. More specifically, in some such examples, repositioning jig 108 may be configured to selectively engage the respective probe assembly mounting structure 160 of at least one probe assembly 120 to bring each respective probe assembly mounting structure to a predetermined position and/or orientation relative to support structure 110. As a more specific example, the repositioning jig may have a fixed and/or reconfigurable configuration that corresponds to a configuration of testing locations 44 such that engaging each probe assembly mounting structure 160 with the repositioning jig operates to move, or facilitate moving, each probe assembly mounting structure to a position such that each probe 130 is at least substantially aligned with a corresponding testing location 44. Repositioning jig 108 may include and/or be any of a variety of suitable structures and/or mechanisms configured to position, to accurately position, to selectively position, to reposition, to accurately reposition, and/or to selectively reposition probe assembly mounting structure 160 on and/or relative to support structure 110. Examples of repositioning jig 108 include a motorized jig, a manually adjustable jig, and/or a robot. In other examples, repositioning jig 108 may include and/or be a template for positioning each probe 130.

In some examples, support structure 110, magnetic plate 114, and/or the respective probe assembly mounting structure 160 of at least one probe assembly 120 may be configured such that the location of each probe assembly mounting structure upon the support structure and/or the magnetic plate is continuously and/or infinitely variable. For example, the respective probe assembly mounting structure 160 of at least one probe assembly 120 may be configured to be magnetically coupled to magnetic plate 114 at any of a continuous plurality and/or distribution of locations and/or rotational configurations relative to the magnetic plate. In this manner, the position and/or configuration of the probe assembly mounting structure relative to the magnetic plate and/or the support structure may be described as being infinitely adjustable.

In some examples, customizable probe card 100 is configured to be selectively and repeatedly operatively coupled to and uncoupled from one or more other components of probe system 10. For example, and as schematically illustrated in FIG. 1, probe system 10 may include a probe card holder 60 that is configured to support customizable probe card 100 relative to substrate 40. Specifically, in such examples, probe card holder 60 is configured such that customizable probe card 100 may be selectively and repeatedly operatively coupled to and uncoupled from the probe card holder. In such examples, and as schematically illustrated in FIG. 1, support structure 110 may include a mounting structure 112 for selectively and repeatedly operatively coupling customizable probe card 100 to probe card holder 60. Probe card holder 60 and/or mounting structure 112 each may include and/or be any of a variety of suitable structures, such as may be known to the art of probe cards, examples of which include a mechanical fastener, a fastener receiver, a press-fit fastener, a socket, and/or a zero insertion force (ZIF) connector. As a more specific example, and as schematically illustrated in FIG. 1, mounting structure 112 may include one or more fasteners 62 that extend at least partially through each of probe card holder 60 and customizable probe card 100.

In some examples, and as schematically illustrated in FIG. 1, probe system 10 includes a platen 50 that supports probe card holder 60 and/or customizable probe card 100 relative to substrate 40. In some such examples, platen 50 includes and/or defines probe card holder 60. Platen 50 and/or probe card holder 60 may support customizable probe card 100 in any of a variety of suitable configurations. As an example, and as schematically illustrated in FIG. 1, platen 50 and/or probe card holder 60 may support customizable probe card 100 such that at least a portion of the customizable probe card is positioned at least substantially below platen 50, and/or such that at least a portion of the customizable probe card is positioned between the platen and chuck 30. More specifically, and as schematically illustrated in FIG. 1, platen 50 and/or probe card holder 60 may support customizable probe card 100 such that support structure 110 is positioned at least substantially below platen 50 and/or such that the support structure is positioned between the platen and chuck 30. In such a configuration, customizable probe card 100 and/or support structure 110 may be described as being suspended by platen 50. Similarly, in some examples, and as schematically illustrated in FIG. 1, each probe repositioning mechanism 106 of probe repositioning assembly 104 (e.g., each probe translation stage 150 and/or each probe assembly mounting structure 160) is supported by and/or operatively coupled to a portion of support structure 110 that extends below platen 50.

In some examples, and as schematically illustrated in FIG. 1, probe system 10 additionally includes an enclosure 12 that at least partially bounds, or defines, an enclosure volume 14. Enclosure volume 14 may be adapted, configured, designed, shaped, sized, and/or constructed to receive and/or to contain chuck 30, substrate 40, platen 50, customizable probe card 100, support structure 110, and/or any suitable portion thereof. In a specific example, platen 50 may at least partially bound and/or define enclosure volume 14 and support structure 110 of customizable probe card 100 may be positioned within the enclosure volume. Enclosure 12 may be an electrically conductive enclosure, and/or may be configured to at least partially shield enclosure volume 14 from the ambient environment that surrounds enclosure 12, that is external to enclosure 12, and/or that is external to enclosure volume 14. As examples, enclosure 12 may shield enclosure volume 14 from electromagnetic radiation that may be present within the ambient environment, from electric fields that may be present within the ambient environment, from magnetic fields that may be present within the ambient environment, and/or from visible light that may be present within the ambient environment. In this manner, enclosure 12 may be configured to provide shielding for each DUT 42 and/or each probe 130 from electromagnetic radiation. In some examples, and as schematically illustrated in FIG. 1, platen 50 at least partially defines enclosure volume 14. In some such examples, enclosure 12 may be described as including platen 50, and/or platen 50 may be described as forming an upper surface of enclosure 12.

In some examples, customizable probe card 100 includes an electrical interface 170 that is configured to transfer electrical signals between probe assembly 120 and a component of probe system 10 exterior to the customizable probe card. As more specific examples, electrical interface 170 may be configured to transfer test signal 72, resultant signal 74, stage control signal 86, and/or electromagnet control signal 94 between probe assembly 120 and signal generation and analysis assembly 70, and/or between the probe assembly and controller 80.

Electrical interface 170 may include and/or be any of a variety of suitable structures, examples of which include an electrical cable connector and/or an electrical contact. In some examples, mounting structure 112 includes electrical interface 170. In some such examples, probe card holder 60 and/or mounting structure 112 may include and/or be a socket that provides each of a mechanical coupling and an electrical coupling between customizable probe card 100 and a component of probe system 10 exterior to the customizable probe card. As a more specific example, probe card holder 60 may include and/or be a socket that is configured to selectively receive at least a portion of customizable probe card 100 such that the probe card holder supports the customizable probe card relative to substrate 40 and such that the probe card holder forms an electrical connection with the customizable probe card. Additionally or alternatively, and as schematically illustrated in FIG. 1, one or more probe assemblies 120 may include respective electrical interfaces 170. As a more specific example, at least one probe assembly 120 and/or the respective probe holder 140 thereof may include a respective electrical interface 170.

As schematically illustrated in FIG. 1, customizable probe card 100 may be characterized by a maximum linear dimension 102 of the customizable probe card. Maximum linear dimension 102 may correspond to any appropriate dimension of customizable probe card 100, such as a length, a width, and/or a diameter of the customizable probe card. Additionally or alternatively, maximum linear dimension 102 may correspond to a diameter of the smallest sphere that can fully encompass (e.g., circumscribe) customizable probe card 100.

Customizable probe card 100 may be configured such that maximum linear dimension 102 is sufficiently small to facilitate handling of the customizable probe card by a human user, such as while selectively coupling the customizable probe card to probe card holder 60 and/or while selectively removing the customizable probe card from the probe card holder. As more specific examples, maximum linear dimension 102 may be at least 5 centimeters (cm), at least 10 cm, at least 20 cm, at least 30 cm, at least 40 cm, at most 50 cm, at most 35 cm, at most 25 cm, at most 15 cm, and/or at most 7 cm.

In some examples, and as further schematically illustrated in FIG. 1, probe system 10 and/or customizable probe card 100 includes at least one imaging device 90 that is configured to receive and/or generate an optical image of at least a portion of probe system 10. Stated differently, each imaging device 90 may be configured to receive and/or collect light that is generated and/or reflected by at least a portion of probe system 10 to form an optical image, and/or each imaging device may be configured to generate and/or transmit an image of a portion of probe system 10 within a field of view of the imaging device. As more specific examples, each imaging device 90 may be configured to generate an optical image of substrate 40, of DUT 42, and/or of a portion of at least one probe assembly 120 that interfaces with a respective testing location 44. In this manner, each imaging device 90 may be configured to facilitate establishing alignment and/or contact between at least one probe 130 with a corresponding DUT 42 and/or a corresponding testing location 44 thereof. Additionally or alternatively, at least one imaging device 90 may be configured to collect electromagnetic radiation, or light, emitted by substrate 40 and/or DUT 42. In this manner, in such examples, each such imaging device 90 may be configured to image substrate 40 and/or DUT 42 without necessitating an external light source to illuminate the substrate and/or the DUT.

In some examples, and as schematically illustrated in FIG. 1, one or more imaging devices 90 may be operatively coupled to and/or incorporated into customizable probe card 100. As a more specific example, probe assembly 120 and/or a portion thereof (such as the respective probe holder 140, the respective probe 130, and/or probe body 132 of the respective probe) may support and/or include a respective imaging device 90. In such examples, each such imaging device 90 may move at least substantially in unison with the respective probe holder 140 and/or with the respective probe 130 as the probe holder and/or the probe is selectively repositioned relative to support structure 110. Such a configuration thus may facilitate and/or obviate an adjustment of imaging device 90 to optimize receiving the optical image of probe 130 and/or of substrate 40 subsequent to selectively reconfiguring customizable probe card 100. Stated differently, in an example in which imaging device 90 is operatively coupled to probe 130 and/or probe holder 140, the imaging device may be configured such that an image of the probe that is generated by the imaging device remains at least partially unchanged as the probe holder is moved relative to support structure 110. As more specific examples, the respective imaging device 90 associated with at least one probe assembly 120 may be operatively coupled to, and/or fixed relative to, the respective probe holder 140 and/or to the respective probe 130 (such as to probe body 132 of the respective probe) such that the respective probe remains in focus to the imaging device and/or within a field of view of the imaging device while the probe holder is moved relative to support structure 110 and/or substrate 40.

Each imaging device 90 may be configured to collect light along any of a variety of directions, such as a direction that is at least substantially parallel to the X-direction, the Y-direction, the Z-direction, and/or normal axis 116 as illustrated in FIG. 1. Each imaging device 90 may include and/or be any suitable structure that may be adapted, configured, designed, and/or constructed to generate one or more optical images of one or more probe assemblies 120 and/or of substrate 40. As examples, each imaging device 90 may include and/or be a microscope, a microscope that includes an eyepiece, a microscope that does not include an eyepiece, a camera, a charge-coupled device, an imaging sensor, a solid-state imaging device, a C-MOS imaging device, and/or a lens. In some examples, at least one imaging device 90 may be operatively supported by a respective probe assembly 120, such as by probe body 132 of the respective probe 130 of the respective probe assembly.

Probe system 10 may be configured to support substrate 40 in any appropriate manner during operative use of customizable probe card 100. In some examples, and as schematically illustrated in FIG. 1, probe system 10 includes a chuck 30 with a chuck support surface 32 that operatively supports substrate 40 during operative use of customizable probe card 100 to test DUT(s) 42. In some examples, and as additionally schematically illustrated in dashed lines in FIG. 1, probe system 10 includes a chuck translation stage 20 with a chuck translation stage support surface 22 that supports chuck 30.

In some examples, chuck translation stage 20 is configured to facilitate repositioning at least a portion of customizable probe card 100 relative to substrate 40. As examples, chuck translation stage 20 may be configured to operatively translate chuck 30 relative to customizable probe card 100 and/or to operatively rotate chuck 30 relative to the customizable probe card, such as to facilitate establishing alignment between one or more DUT(s) 42 and one or more respective probe(s) 130 to prepare probe system 10 for testing of the DUT(s). Additionally or alternatively, chuck translation stage 20 may be configured to operatively translate and/or rotate chuck 30 relative to customizable probe card 100 so as to facilitate sequential testing of a plurality of DUTs 42 by the customizable probe card, such as by moving substrate 40 relative to customizable probe card 100 such that the respective probe 130 of at least one probe assembly 120 is aligned with a different DUT and/or a different testing location 44.

Chuck translation stage 20 may be configured to translate chuck 30 and/or substrate 40 relative to customizable probe card 100 along any of a plurality of directions and/or axes, such as along a first axis and along a second axis that is perpendicular, or at least substantially perpendicular, to the first axis. The first axis and the second axis both may be parallel, or at least substantially parallel, to chuck translation stage support surface 22. For example, the first axis may be oriented in the X-direction as illustrated in FIG. 1, and/or the second axis may be oriented in the Y-direction as illustrated in FIG. 1 (or vice versa). Chuck translation stage 20 additionally or alternatively may be configured to operatively and/or simultaneously translate chuck 30 and/or substrate 40 relative to customizable probe card 100 along a third axis that is perpendicular, or at least substantially perpendicular, to chuck translation stage support surface 22. For example, the third axis may be oriented in the Z-direction as illustrated in FIG. 1, and/or may be parallel to normal axis 116 as illustrated in FIG. 1. Additionally or alternatively, chuck translation stage 20 may be configured to operatively and/or simultaneously rotate chuck 30 and/or substrate 40 about a rotation axis. The rotation axis may be perpendicular, or at least substantially perpendicular, to chuck translation stage support surface 22, and/or may be the third axis.

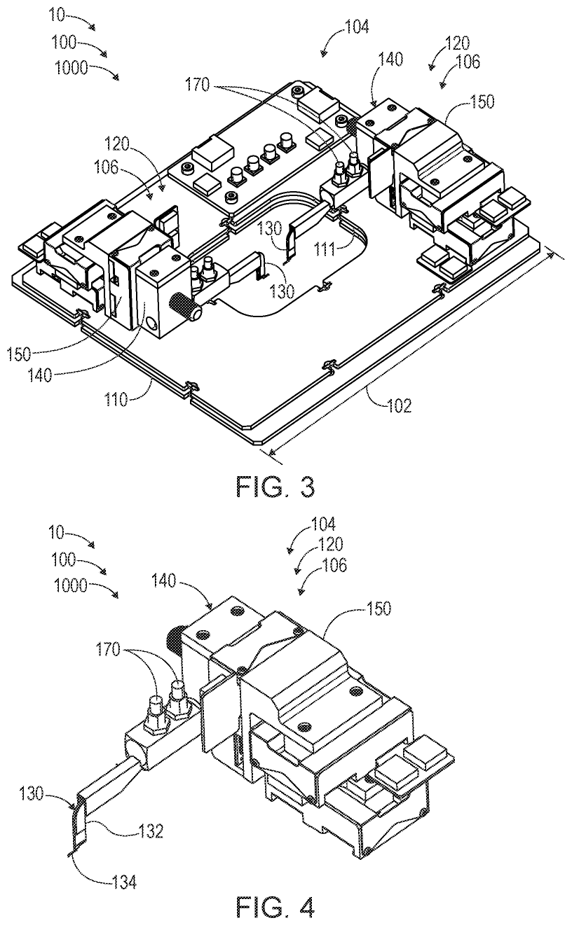

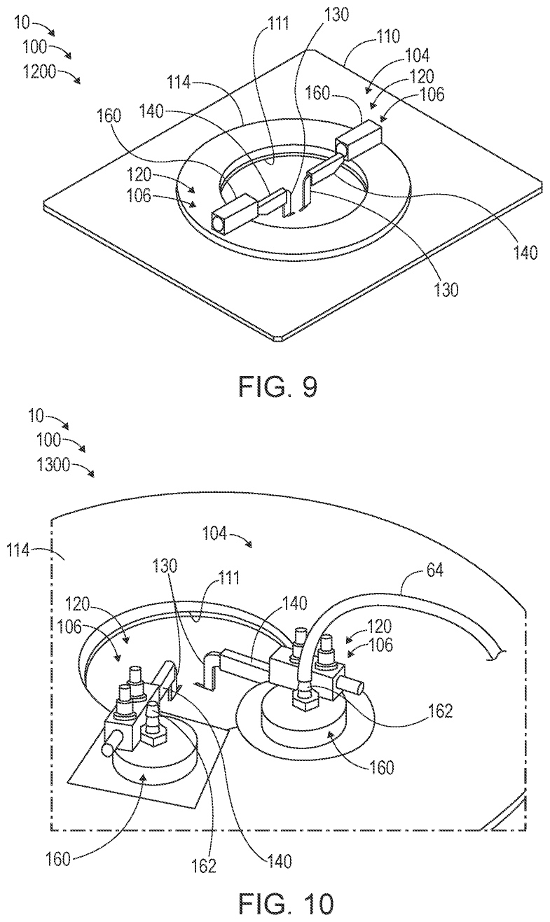

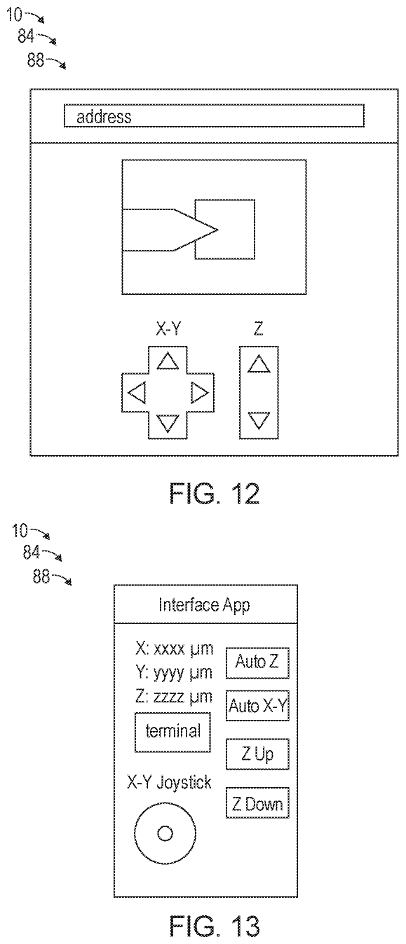

Turning now to FIGS. 3-13, FIGS. 3-8 are less schematic illustrations of examples of customizable probe cards 100 in which the respective probe repositioning mechanism 106 of each probe assembly 120 includes a respective probe translation stage 150. As described in more detail below, FIGS. 9-11 are less schematic illustrations of examples of customizable probe cards 100 in which the respective probe repositioning mechanism 106 of each probe assembly 120 includes a respective probe assembly mounting structure 160. As described in more detail below, FIGS. 12-13 illustrate examples of user interfaces 88 that may be associated with user interface device 84. It is within the scope of the present disclosure that any of the features, aspects, components, etc. illustrated in conjunction with probe systems 10 of any of FIGS. 3-13 additionally or alternatively may be utilized in conjunction with probe systems 10 of any other of FIGS. 3-13.

FIGS. 3-6 illustrate a customizable probe card 1000, which is an example of customizable probe card 100. As shown in FIG. 3, customizable probe card 1000 includes two probe assemblies 120, each of which includes a portion of probe repositioning assembly 104 in the form of a respective probe repositioning mechanism 106 that includes a respective probe translation stage 150. In this example, probe translation stage 150 of customizable probe card 1000 is a motorized translation stage.

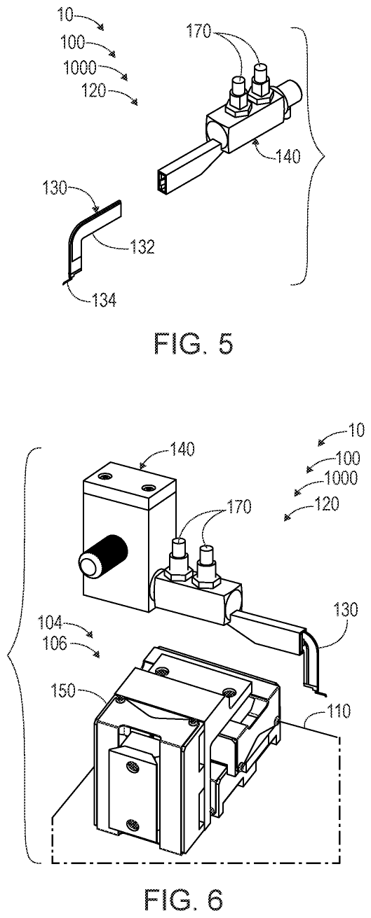

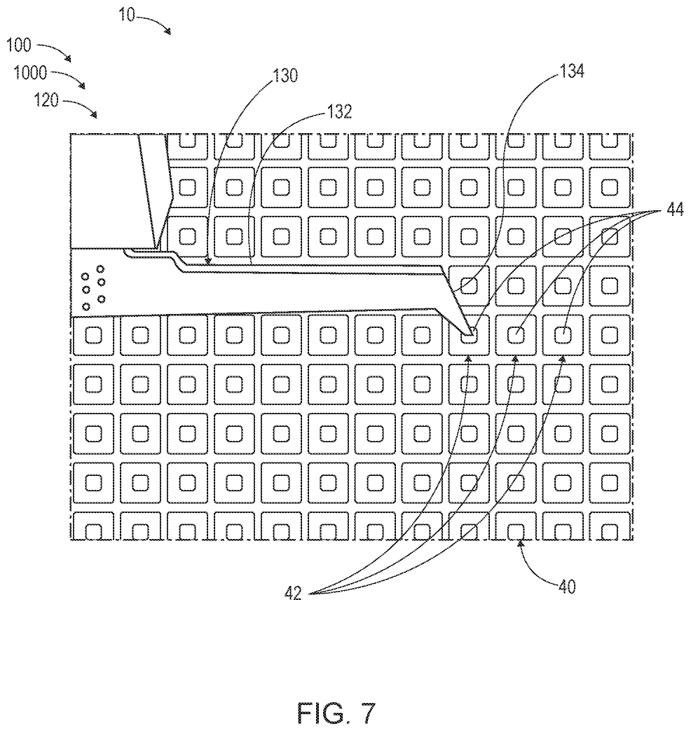

As shown in FIGS. 3-6, and as perhaps best seen in FIGS. 5-6, each probe assembly 120 of customizable probe card 1000 includes a respective probe holder 140 that is supported by the respective probe translation stage 150 and that receives a respective probe 130. In particular, in this example, each probe holder 140 is configured such that the respective probe 130 may be selectively removed from the probe holder and inserted into the probe holder, such as to facilitate exchanging the probe 130 for a new probe if the probe becomes damaged or otherwise is not well suited to test a particular DUT 42. FIG. 7 illustrates a particular probe 130 of customizable probe card 100 positioned relative to an example of substrate 40 including a plurality of DUTs 42 with respective testing locations 44. In particular, in the configuration illustrated in FIG. 7, probe tip 134 of probe 130 is positioned to contact the respective testing location 44 of a particular DUT 42 on substrate 40.

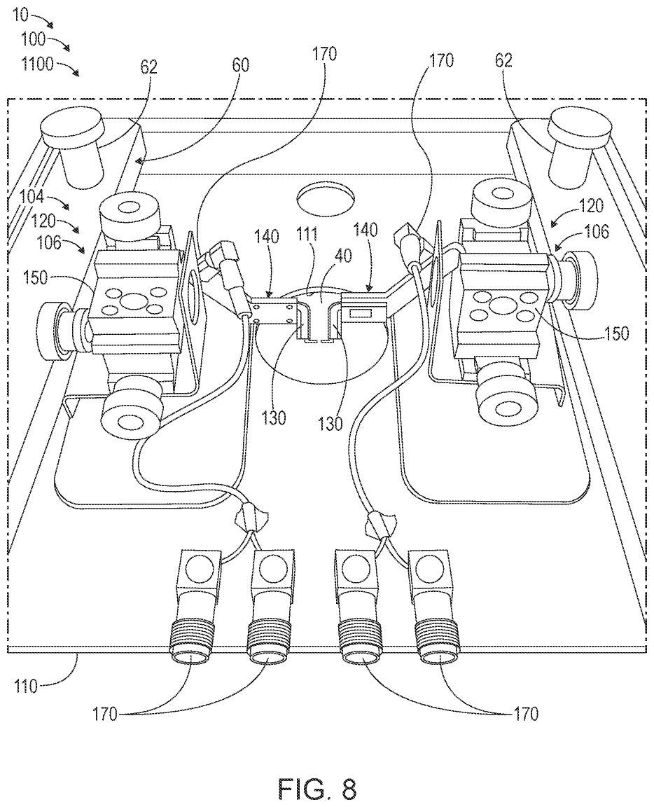

FIG. 8 illustrates a customizable probe card 1100, which is another example of customizable probe card 100. Customizable probe card 1100 is substantially similar to customizable probe card 1000 of FIGS. 3-7 with the exception that the respective probe translation stage 150 of each probe assembly 120 is a manually adjustable translation stage.

FIG. 9 illustrates a customizable probe card 1200, which is another example of customizable probe card 100. As illustrated in FIG. 9, support structure 110 of customizable probe card 1200 includes magnetic plate 114, and the respective probe repositioning mechanism 106 of each probe assembly 120 of customizable probe card 1200 includes a respective probe assembly mounting structure 160 that is selectively magnetically coupled to magnetic plate 114.

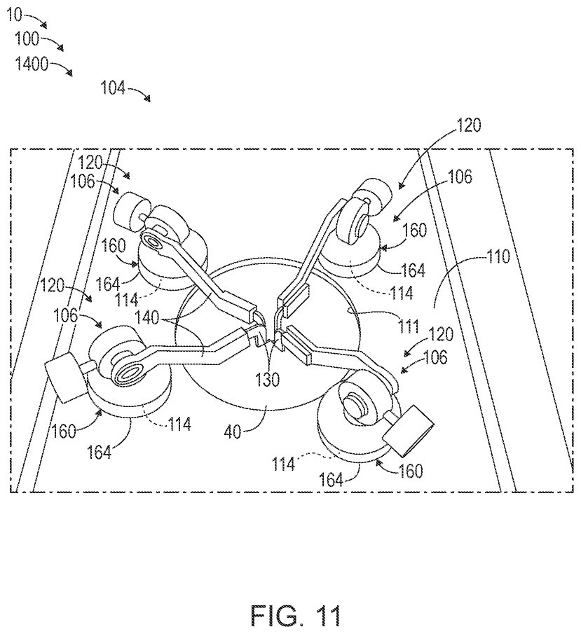

FIG. 10 illustrates a customizable probe card 1300, which is another example of customizable probe card 100. Customizable probe card 1300 is substantially similar to customizable probe card 1200. Specifically, support structure 110 of customizable probe card 1300 also includes magnetic plate 114, and the respective probe repositioning mechanism 106 of each probe assembly 120 of customizable probe card 1300 includes a respective probe assembly mounting structure 160 that is selectively magnetically coupled to magnetic plate 114. However, and as illustrated in FIG. 10, each probe assembly mounting structure 160 of customizable probe card 1300 additionally includes gas connector 162 that is configured to be operatively fluidly coupled to gas conduit 64 of probe system 10. Specifically, in this example, introducing a pressurized flow gas to each probe assembly mounting structure 160 via gas source 66 (schematically illustrated in FIG. 1) and gas connector 162 operates to introduce an air cushion between the probe assembly mounting structure and magnetic plate 114, thereby facilitating repositioning the probe assembly mounting structure relative to magnetic plate 114.

FIG. 11 illustrates a customizable probe card 1400, which is another example of customizable probe card 100. Similar to customizable probe card 1200 of FIG. 9 and customizable probe card 1300 of FIG. 10, customizable probe card 1400 includes a plurality of probe assembly mounting structures 160 that each are configured to be magnetically retained in position relative to support structure 110. In the example of FIG. 11, probe repositioning assembly 104 includes a plurality of spaced-apart magnetic plates 114 such that each probe assembly mounting structure 160 is magnetically coupled to a respective magnetic plate. In the example of FIG. 11, each magnetic plate 114 is concealed from view by the respective probe assembly mounting structure 160.

FIG. 11 additionally illustrates an example in which each probe assembly mounting structure 160 is configured to be manually translated relative to the respective magnetic plate 114 while remaining magnetically coupled to the magnetic plate and without diminishing a strength of the magnetic coupling. In order to facilitate manual alignment of each probe 130 of customizable probe card 1400 with desired locations on substrate 40, customizable probe card 1400 may be utilized in conjunction with imaging device 90 (e.g., as schematically illustrated in FIG. 1). More specifically, in such examples, a user may view a visual representation, such as a real-time video, representing a location of probe 130 relative to substrate 40 and/or relative to a target location on the substrate while manually urging each probe assembly mounting structure 160 to move relative to support structure 110. In such examples, the target location may be DUT 42 and/or testing location 44, as schematically illustrated in FIG. 1, and/or may be a virtual target location that is visually superimposed on the optical image generated by imaging device 90.

FIGS. 12-13 represent schematic illustrations of examples of user interfaces 88 that may be utilized to at least partially control operation of customizable probe card 100, probe repositioning assembly 104, and/or probe translation stage(s) 150. For example, and as discussed above with reference to FIG. 1, probe system 10 may include controller 80 that is configured to receive a wireless control signal 82 from a user interface device 84 and to transmit a stage control signal 86 to the respective probe translation stage 150 of at least one probe assembly 120. Accordingly, FIGS. 12-13 schematically illustrate examples of user interfaces 88 that may be generated and/or presented by user interface device 84 to a human user and to receive an input from the user, thus enabling the user to at least partially control the operation of at least one probe translation stage 150.

More specifically, FIG. 12 schematically illustrates an example of user interface 88 in the form of an Internet-based interface that provides the user with controls for manipulating at least one probe 130 via the respective probe translation stage. In the example of FIG. 12, user interface 88 additionally provides the user with an image, such as a real-time image, of at least a portion of customizable probe card 100 and/or of substrate 40, such as may be collected by imaging device 90. In this manner, user interface 88 of FIG. 12 may enable the user to position probe 130 relative to a corresponding DUT 42 with reference to a real-time image of the probe relative to the DUT. In the example of FIG. 13, user interface 88 takes the form of a screen presented by a mobile device application. In this example, user interface 88 provides the user with manual and/or semi-automated control of at least one probe translation stage 150, and additionally provides the user with information regarding a position of the respective probe(s) 130 relative to substrate 40, DUT 42, and/or testing location 44.

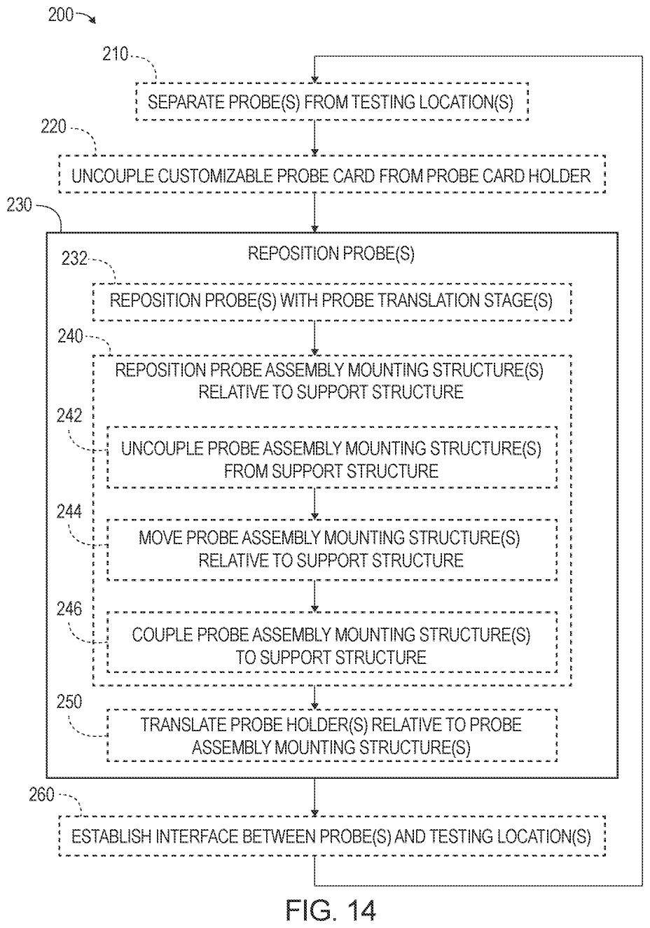

FIG. 14 is a flowchart depicting methods 200, according to the present disclosure, of reconfiguring a customizable probe card of a probe system, such as to selectively adapt the customizable probe card for testing of a given substrate and/or DUT(s) thereof. Examples of probe systems and/or customizable probe cards that may be utilized in conjunction with methods 200 are described herein with reference to probe system 10 and/or customizable probe card 100 thereof, respectively. Examples of substrates and/or DUTs that may be utilized in conjunction with methods 200 are described herein with reference to substrate 40 and/or DUT(s) 42, respectively.

As shown in FIG. 14, and as discussed in more detail below, a method 200 includes repositioning, at 230 and utilizing a probe repositioning assembly, a respective probe of at least one probe assembly of the customizable probe card. Examples of probe repositioning assemblies, probe assemblies, and/or probes that may be utilized in conjunction with methods 200 are described herein with reference to probe repositioning assembly 104, probe assembly 120, and/or probe 130, respectively.

The repositioning the probe(s) at 230 may include repositioning in any of a variety of circumstances and/or manners. For example, the repositioning the probe(s) at 230 may include bringing one or more probes of the customizable probe card to a selected and/or desired position, such as relative to the substrate, relative to one or more DUTs, and/or relative to one or more testing locations. In this manner, and as discussed herein, the repositioning the probe(s) at 230 may operate to configure the customizable probe card such that the absolute and/or relative positions and/or orientations of the probes and/or of respective probe tips of the probes correspond to a relative orientation of testing locations of the substrate and/or DUT(s) that will be tested.

Stated differently, the repositioning the probe(s) at 230 may include bringing the probe(s) to respective positions and/or orientations that correspond to a pattern, a layout, a configuration, etc. of testing locations to be tested by the probe(s). Additionally or alternatively, the repositioning the probe(s) at 230 may include repositioning the probe(s) to correct a misalignment of the probe(s), such as relative to one another, relative to the substrate, and/or relative to another component of the customizable probe card. Stated differently, in such examples, the repositioning the probe(s) may include repositioning to correct the position(s) and/or orientation(s) of the probe(s), such as of one or more probes that are only approximately correctly positioned. As another example, the repositioning at 230 may include replacing a probe and/or a probe assembly of the customizable probe card, such as to repair and/or replace a probe tip that is damaged and/or contaminated. Examples of testing locations that may be utilized in conjunction with methods 200 are described herein with reference to testing locations 44.

The repositioning the probe(s) at 230 may be performed in any of a variety of manners, such as in any suitable manner described herein. As an example, and as shown in FIG. 2, the repositioning at 230 may include repositioning, at 232, each probe with a respective probe translation stage of the probe repositioning assembly. As more specific examples, the repositioning with the probe translation stage(s) at 232 may include translating the respective probe and/or the respective probe holder of each probe assembly relative to a support structure of the customizable probe card along one or more linear dimensions and/or rotating the respective probe holder(s) relative to the support structure. Examples of support structures, probe holders, and/or probe translation stages that may be utilized in conjunction with methods 200 are described herein with reference to support structure 110, probe holder 140, and/or probe translation stage 150, respectively.

In some examples, the repositioning the probe(s) at 232 includes controlling the respective probe translation stage of at least one probe assembly at least partially remotely, such as via a stage control signal that is generated and/or transmitted via a controller. Examples of controllers and/or stage control signals are described herein with reference to controller 80 and/or stage control signal 86, respectively. Additionally, the repositioning the probe(s) at 232 may include utilizing the probe repositioning assembly and/or the probe translation stage in conjunction with any other structures and/or mechanisms discussed herein in association with probe translation stage 150.

Additionally or alternatively, and as shown in FIG. 14, the probe repositioning assembly and/or at least one probe assembly may include a respective probe assembly mounting structure, and the repositioning the probe(s) at 230 may include repositioning, at 240, the respective probe assembly mounting structure of at least one such probe assembly relative to the support structure. As a more specific example, the repositioning the probe assembly mounting structure(s) at 240 may include translating the respective probe assembly mounting structure(s) along a direction at least substantially perpendicular to a normal axis associated with the customizable probe card, such as normal axis 116 described herein. In some examples, and as shown in FIG. 14, the repositioning the probe assembly mounting structure(s) at 240 includes moving, at 244, each probe assembly mounting structure to a different location and/or rotational orientation upon the support structure.

As discussed, when present, a probe assembly mounting structure (such as probe assembly mounting structure 160 described herein) generally is configured to be selectively moved (e.g., translated and/or rotated) relative to the support structure and to be fixed in position relative to the support structure to operatively position the respective probe for testing of the DUT(s). In some examples, and as discussed herein, the probe assembly mounting structure is configured such that a force (e.g., a magnetic force and/or a suction force) that retains the probe assembly mounting structure relative to the support structure may be selectively reduced, mitigated, and/or opposed to facilitate the moving the probe assembly mounting structure(s) at 244. Accordingly, in such examples, and as shown in FIG. 14, the repositioning the probe assembly mounting structure(s) at 240 may include, prior to the moving the probe assembly mounting structure(s) at 244, uncoupling, at 242, each probe assembly mounting structure from the support structure. Additionally or alternatively, in such examples, and as shown in FIG. 14, the repositioning the probe assembly mounting structure(s) at 240 may include, subsequent to the moving the probe assembly mounting structure(s) at 244, coupling, at 246, each probe assembly mounting structure to the support structure.

In an example in which the probe repositioning assembly of the customizable probe card includes one or more probe assembly mounting structures, the repositioning the probe assembly mounting structure(s) at 240 may include utilizing the probe repositioning assembly and/or each probe assembly mounting structure in conjunction with any structures and/or mechanisms discussed herein in association with probe assembly mounting structure 160. For example, the repositioning the probe assembly mounting structure(s) at 240 may include selectively utilizing one or more structures and/or mechanisms configured for selectively retaining each probe assembly mounting structure relative to the support structure and/or for facilitating repositioning of each probe assembly mounting structure relative to the support structure. As an example, and as discussed, the probe assembly mounting structure may be configured to be operatively coupled to a magnetic plate, such as magnetic plate 114 described herein, via a magnetic force. In such an example, the uncoupling the probe assembly mounting structure(s) at 242 may include conveying a pressurized flow of gas, such as air, to the interface between the probe assembly mounting structure and the magnetic plate to at least partially urge the probe assembly mounting structure away from the magnetic plate and/or to reduce the friction between the probe assembly mounting structure and the magnetic plate.

As discussed herein, in such examples, the uncoupling the probe assembly mounting structure(s) at 242 may include generating the pressurized flow with a gas source, conveying the pressurized flow through a gas conduit to the probe assembly mounting structure and/or to the magnetic plate, and/or regulating the pressurized flow with a valve. Similarly, in such an example, the coupling the probe assembly mounting structure(s) at 246 may include restricting the pressurized flow, such as with the valve, such that the magnetic force between the probe assembly mounting structure and the magnetic plate maintains the probe assembly mounting structure in position relative to the support structure. In such examples, the regulating the pressurized flow with the valve and/or the restricting the pressurized flow with the valve may include controlling the valve remotely, such as by sending a valve control signal from the controller to the valve. Examples of such gas conduits, valves, valve control signals, and/or gas sources are described herein with reference to gas conduit 64, valve 65, valve control signal 96, and/or gas source 66, respectively.

As another example, one or both of the probe assembly mounting structure and the magnetic plate may include an electromagnet that may be selectively magnetized and demagnetized to selectively increase and decrease the magnitude of the magnetic force between the probe assembly mounting structure and the magnetic plate. In such an example, the uncoupling the probe assembly mounting structure(s) at 242 may include selectively demagnetizing the electromagnet(s) to remove the magnetic force, and/or the coupling the probe assembly mounting structure(s) at 246 may include selectively magnetizing the electromagnet(s) to apply the magnetic force. As more specific examples, the uncoupling the probe assembly mounting structure(s) at 242 and/or the coupling the probe assembly mounting structure(s) at 246 may include transmitting an electromagnet control signal, such as electromagnet control signal 94 described herein, from the controller to the electromagnet.

As another example, and as discussed, the probe assembly mounting structure may be configured to be operatively coupled to (e.g., retained against) the support structure and/or the magnetic plate via a suction force, such as a suction force produced by applying a vacuum to the interface between the probe assembly mounting structure and the support structure. Accordingly, in such examples, the coupling the probe assembly mounting structure(s) at 246 may include applying a vacuum to the interface region between the probe assembly mounting structure and the support structure (and/or between the probe assembly mounting structure and the magnetic plate) by drawing air through a gas conduit, thereby selectively retaining the probe assembly mounting structure relative to the support structure via a suction force. Similarly, in such examples, the uncoupling the probe assembly mounting structure(s) at 242 may include interrupting and/or ceasing the drawing of the air through the gas conduit, such as by restricting the flow of gas through the gas conduit with the valve, thereby reducing and/or removing the suction force retaining the probe assembly mounting structure against the support structure.

The foregoing examples generally correspond to examples in which a force (e.g., a magnetic force and/or a suction force) retaining each probe assembly mounting structure relative to the support structure and/or the magnetic plate may be selectively reduced, mitigated, and/or opposed to facilitate the moving the probe assembly mounting structure(s) at 244. However, and as discussed, this is not required of all examples of methods 200, and it is additionally within the scope of the present disclosure that the moving the probe assembly mounting structure(s) at 244 may include moving each probe assembly mounting structure while the probe assembly mounting structure remains operatively magnetically coupled to the magnetic plate.

In some examples, and as discussed, the probe repositioning assembly may include a repositioning jig, and the moving the probe assembly mounting structure(s) at 244 may include operatively engaging each probe assembly mounting structure with the repositioning jig to bring each probe assembly mounting structure to a predetermined location and/or rotational orientation relative to the support structure. Examples of such repositioning jigs are discussed herein with reference to repositioning jig 108. As discussed, in some examples, the customizable probe card is configured to be selectively and repeatedly operatively coupled to and uncoupled from a probe card holder, such as probe card holder 60 described herein. In such examples, the repositioning the probe(s) at 230 may be performed while the customizable probe card remains operatively coupled to the probe card holder and/or operatively installed within the probe system. Stated differently, customizable probe cards 100 and/or methods 200 according to the present disclosure may enable selective reconfiguration of the customizable probe card without removing the customizable probe card from the probe card holder.

However, in such examples, it may be desirable to ensure that each probe is spaced apart from the substrate prior to repositioning the probes. Accordingly, in some such examples and as shown in FIG. 14, methods 200 further include, prior to the repositioning the probe(s) at 230, separating, at 210, each probe from the corresponding testing location. As examples, the separating the probe(s) at 210 may include removing each probe from contact with the corresponding testing location and/or increasing a distance between each probe and the substrate. In such examples, methods 200 additionally may include, subsequent to the repositioning the probe(s) at 230, establishing, at 260, an operative interface between each probe and the corresponding testing location. As examples, the establishing the interface at 260 may include contacting each probe to the corresponding testing location, or may include positioning each probe relative to the corresponding testing location to establish a non-contact testing interface between the probe and the testing location.

The separating the probe(s) at 210 and/or the establishing the interface at 260 may include moving each probe relative to the substrate and/or relative to the corresponding DUTs in any appropriate manner, such as by moving one or more probes with respective probe repositioning mechanisms of the respective probe assemblies and/or of the probe repositioning assembly and/or by moving the substrate with a chuck translation stage. Examples of probe repositioning mechanisms are described herein with reference to probe repositioning mechanism 106, such as may include and/or be probe translation stage 150 and/or probe assembly mounting structure 160. Examples of chuck translation stages are described herein with reference to chuck translation stage 20.

In some examples, and as discussed, each probe assembly mounting structure additionally or alternatively may be configured to enable repositioning the respective probe and/or the respective probe holder relative to the support structure along a direction at least substantially parallel to the normal axis, such as by selectively translating the respective probe holder relative to the probe assembly mounting structure. Accordingly, in such examples, and as shown in FIG. 14, the repositioning the probe(s) at 230 may include translating, at 250, the respective probe holder of at least one probe assembly relative to the respective probe assembly mounting structure, such as along a direction at least substantially parallel to the normal axis. In such examples, the translating the respective probe holder(s) at 250 may be performed with the customizable probe card operatively coupled to the probe card holder and/or prior to the establishing the interface at 260. As a more specific example, the respective probe holder may be operatively coupled to the probe assembly mounting structure at least partially via a magnetic force, and the translating the probe holder(s) at 250 may be performed while the respective probe holder is operatively and magnetically coupled to the respective probe assembly mounting structure.

In some examples, and as further shown in FIG. 14, methods 200 additionally or alternatively may include, prior to the repositioning the probe(s) at 230, uncoupling, at 220, the customizable probe card from the probe card holder. In such examples, the repositioning the probe(s) at 230 may be performed with the customizable probe card removed from the probe system.

As further shown in FIG. 14, methods 200 may include repeating one or more of the separating the probe(s) at 210, the uncoupling the customizable probe card at 220, the repositioning the probe(s) at 230, the repositioning the probe holder(s) at 232, the repositioning the probe assembly mounting structure(s) at 240, the uncoupling the probe assembly mounting structure(s) at 242, the moving the probe assembly mounting structure(s) at 244, the coupling the probe assembly mounting structure(s) at 246, and/or the establishing the interface at 260. In this manner, repeating one or more steps of methods 200 may enable and/or correspond with reconfiguring the customizable probe card for use with substrates and/or DUTs with distinct patterns and/or configurations of testing locations. As an example, the repositioning the probe(s) at 230 may include bringing each probe assembly of the customizable probe card to a first probe configuration for testing one or more DUTs in a first DUT configuration, and method 200 may include repeating the repositioning at 230 to bring each probe assembly of the customizable probe card to a second probe configuration for testing one or more DUTs in a second DUT configuration that is different than the first DUT configuration.

As used herein, the term “and/or” placed between a first entity and a second entity means one of (1) the first entity, (2) the second entity, and (3) the first entity and the second entity. Multiple entities listed with “and/or” should be construed in the same manner, i.e., “one or more” of the entities so conjoined. Other entities may optionally be present other than the entities specifically identified by the “and/or” clause, whether related or unrelated to those entities specifically identified. Thus, as a non-limiting example, a reference to “A and/or B,” when used in conjunction with open-ended language such as “comprising” may refer, in one embodiment, to A only (optionally including entities other than B); in another embodiment, to B only (optionally including entities other than A); in yet another embodiment, to both A and B (optionally including other entities). These entities may refer to elements, actions, structures, steps, operations, values, and the like.

As used herein, the phrase “at least one,” in reference to a list of one or more entities should be understood to mean at least one entity selected from any one or more of the entity in the list of entities, but not necessarily including at least one of each and every entity specifically listed within the list of entities and not excluding any combinations of entities in the list of entities. This definition also allows that entities may optionally be present other than the entities specifically identified within the list of entities to which the phrase “at least one” refers, whether related or unrelated to those entities specifically identified. Thus, as a non-limiting example, “at least one of A and B” (or, equivalently, “at least one of A or B,” or, equivalently “at least one of A and/or B”) may refer, in one embodiment, to at least one, optionally including more than one, A, with no B present (and optionally including entities other than B); in another embodiment, to at least one, optionally including more than one, B, with no A present (and optionally including entities other than A); in yet another embodiment, to at least one, optionally including more than one, A, and at least one, optionally including more than one, B (and optionally including other entities). In other words, the phrases “at least one,” “one or more,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C” and “A, B, and/or C” may mean A alone, B alone, C alone, A and B together, A and C together, B and C together, A, B and C together, and optionally any of the above in combination with at least one other entity.

As used herein the terms “adapted” and “configured” mean that the element, component, or other subject matter is designed and/or intended to perform a given function. Thus, the use of the terms “adapted” and “configured” should not be construed to mean that a given element, component, or other subject matter is simply “capable of” performing a given function but that the element, component, and/or other subject matter is specifically selected, created, implemented, utilized, programmed, and/or designed for the purpose of performing the function. It is also within the scope of the present disclosure that elements, components, and/or other recited subject matter that is recited as being adapted to perform a particular function may additionally or alternatively be described as being configured to perform that function, and vice versa.

As used herein, the phrase “at least substantially,” when modifying a degree or relationship, includes not only the recited “substantial” degree or relationship, but also the full extent of the recited degree or relationship. A substantial amount of a recited degree or relationship may include at least 75% of the recited degree or relationship. For example, a first direction that is at least substantially parallel to a second direction includes a first direction that is within an angular deviation of 22.5° relative to the second direction and also includes a first direction that is identical to the second direction.

As used herein, the terms “selective” and “selectively,” when modifying an action, movement, configuration, or other activity of one or more components or characteristics of an apparatus, mean that the specific action, movement, configuration, or other activity is a direct or indirect result of one or more dynamic processes, as described herein. The terms “selective” and “selectively” thus may characterize an activity that is a direct or indirect result of user manipulation of an aspect of, or one or more components of, the apparatus, or may characterize a process that occurs automatically, such as via the mechanisms disclosed herein.

As used herein, the phrase, “for example,” the phrase, “as an example,” and/or simply the term “example,” when used with reference to one or more components, features, details, structures, and/or embodiments according to the present disclosure, are intended to convey that the described component, feature, detail, structure, and/or embodiment is an illustrative, non-exclusive example of components, features, details, structures, and/or embodiments according to the present disclosure. Thus, the described component, feature, detail, structure, and/or embodiment is not intended to be limiting, required, or exclusive/exhaustive; and other components, features, details, structures, and/or embodiments, including structurally and/or functionally similar and/or equivalent components, features, details, structures, and/or embodiments, are also within the scope of the present disclosure.

In the event that any patents, patent applications, or other references are incorporated by reference herein and (1) define a term in a manner that is inconsistent with and/or (2) are otherwise inconsistent with, either the non-incorporated portion of the present disclosure or any of the other incorporated references, the non-incorporated portion of the present disclosure shall control, and the term or incorporated disclosure therein shall only control with respect to the reference in which the term is defined and/or the incorporated disclosure was present originally.

In the present disclosure, several of the illustrative, non-exclusive examples have been discussed and/or presented in the context of flow diagrams, or flow charts, in which the methods are shown and described as a series of blocks, or steps. Unless specifically set forth in the accompanying description, it is within the scope of the present disclosure that the order of the blocks may vary from the illustrated order in the flow diagram, including with two or more of the blocks (or steps) occurring in a different order, concurrently, and/or repeatedly. It is also within the scope of the present disclosure that the blocks, or steps, may be implemented as logic, which also may be described as implementing the blocks, or steps, as logics. In some applications, the blocks, or steps, may represent expressions and/or actions to be performed by functionally equivalent circuits or other logic devices. The illustrated blocks may, but are not required to, represent executable instructions that cause a computer, processor, and/or other logic device to respond, to perform an action, to change states, to generate an output or display, and/or to make decisions.

The various disclosed elements of apparatuses and systems and steps of methods disclosed herein are not required to all apparatuses, systems, and methods according to the present disclosure, and the present disclosure includes all novel and non-obvious combinations and subcombinations of the various elements and steps disclosed herein. Moreover, one or more of the various elements and steps disclosed herein may define independent inventive subject matter that is separate and apart from the whole of a disclosed apparatus, system, or method. Accordingly, such inventive subject matter is not required to be associated with the specific apparatuses, systems, and methods that are expressly disclosed herein and such inventive subject matter may find utility in apparatuses, systems, and/or methods that are not expressly disclosed herein.

Illustrative, non-exclusive examples of probe systems according to the present disclosure are presented in the following enumerated paragraphs:

A1. A customizable probe card for testing one or more devices under test (DUTs), the customizable probe card comprising:

a support structure; and

one or more probe assemblies supported by the support structure, wherein each probe assembly of the one or more probe assemblies includes:

(i) a respective probe, optionally wherein each probe assembly of the one or more probe assemblies includes a respective probe holder that supports the respective probe; and

(ii) a probe repositioning assembly configured to facilitate selective adjustment of an orientation of the respective probe of at least one probe assembly of the one or more probe assemblies relative to the support structure.

A2. The customizable probe card of paragraph A1, wherein the customizable probe card is configured to be selectively reconfigured for operative use with each of a plurality of distinct DUTs by selectively repositioning the respective probe of at least one probe assembly of the one or more probe assemblies relative to the support structure.

A3. The customizable probe card of any of paragraphs A1-A2, wherein the probe repositioning assembly is configured to facilitate one or more of:

(i) selectively repositioning the each probe assembly of the one or more probe assemblies relative to the support structure;

(ii) selectively repositioning the respective probe of at least one probe assembly of the one or more probe assemblies relative to the support structure; and

(iii) selectively repositioning the respective probe holder of at least one probe assembly of the one or more probe assemblies relative to the support structure.

A4. The customizable probe card of any of paragraphs A1-A3, wherein the support structure supports the one or more probe assemblies such that each probe assembly of the one or more probe assemblies is operatively coupled to an upper side of the support structure when the customizable probe card is in operative use to test one or more DUTs positioned below the support structure.

A5. The customizable probe card of any of paragraphs A1-A4, wherein the support structure includes, and optionally is, one or more of a surface that is at least substantially flat, a surface that is at least substantially planar, a plate, a rigid plate, an electrically conductive plate, an electrically insulating plate, an at least partially dielectric plate, and an at least partially metallic plate.

A6. The customizable probe card of any of paragraphs A1-A5, wherein the customizable probe card defines a normal axis; and wherein the support structure extends at least substantially perpendicular to the normal axis.

A7. The customizable probe card of any of paragraphs A1-A6, wherein at least a portion of the probe repositioning assembly forms a portion of at least one probe assembly of the one or more probe assemblies.

A8. The customizable probe card of any of paragraphs A1-A7, wherein the probe repositioning assembly is at least partially defined by at least one probe assembly of the one or more probe assemblies.

A9. The customizable probe card of any of paragraphs A1-A8, wherein the probe repositioning assembly includes, and optionally is, one or more probe repositioning mechanisms; and wherein at least one probe assembly of the one or more probe assemblies includes a respective probe repositioning mechanism of the one or more probe repositioning mechanisms.

A10. The customizable probe card of any of paragraphs A1-A9, wherein one or both of:

(i) at least one probe assembly of the one or more probe assemblies is operatively coupled to the support structure to support the respective probe relative to the support structure; and

(ii) the respective probe holder of at least one probe assembly of the one or more probe assemblies is operatively coupled to the support structure to support the respective probe relative to the support structure.

A11. The customizable probe card of any of paragraphs A1-A10, wherein the support structure defines an aperture, and wherein at least a portion of at least one probe assembly of the one or more probe assemblies extends through the aperture.

A12. The customizable probe card of paragraph A11, wherein at least one probe assembly of the one or more probe assemblies is configured such that one or both of the respective probe holder and the respective probe extends through the aperture during operative use of the customizable probe card.

A13. The customizable probe card of any of paragraphs A9-A12, further comprising one or more probe translation stages; wherein each probe translation stage of the one or more probe translation stages is configured to facilitate selective adjustment of an orientation of the respective probe of at least one probe assembly of the one or more probe assemblies relative to the support structure; optionally wherein the probe repositioning assembly includes, and optionally is, the one or more probe translation stages; optionally wherein each probe assembly of the one or more probe assemblies includes a respective probe translation stage of the one or more probe translation stages; optionally wherein the respective probe repositioning mechanism of at least one probe assembly of the one or more probe assemblies includes, and optionally is, a respective probe translation stage of the one or more probe translation stages; optionally wherein the respective probe translation stage operatively supports one or both of the respective probe holder and the respective probe relative to the support structure; and optionally wherein the respective probe translation stage is configured to selectively reposition one or both of the respective probe holder and the respective probe relative to the support structure.

A14. The customizable probe card of paragraph A13, wherein the respective probe translation stage of at least one probe assembly of the one or more probe assemblies is configured to one or both of:

(i) translate one or both of the respective probe holder and the respective probe relative to the support structure along one or more linear dimensions; and

(ii) rotate one or both of the respective probe holder and the respective probe relative to the support structure.

A15. The customizable probe card of paragraph A14, wherein the one or more linear dimensions includes one or both of:

(i) a dimension that extends at least substantially parallel to a/the normal axis; and

(ii) a dimension that extends at least substantially perpendicular to the normal axis.

A16. The customizable probe card of any of paragraphs A13-A15, wherein one or both of the respective probe holder and the respective probe is configured to be selectively and repeatedly operatively coupled to and uncoupled from the respective probe translation stage.

A17. The customizable probe card of any of paragraphs A13-A16, wherein the respective probe translation stage of each probe assembly of the one or more probe assemblies is fixedly coupled to the support structure during operative use of the customizable probe card and is configured to adjust the orientation of the respective probe relative to the support structure.

A18. The customizable probe card of any of paragraphs A13-A17, wherein the respective probe translation stage of at least one probe assembly of the one or more probe assemblies is configured to be selectively and repeatedly operatively coupled to and uncoupled from the support structure without damage to the respective probe translation stage.

A19. The customizable probe card of any of paragraphs A13-A18, wherein the respective probe translation stage includes, and optionally is, a motorized translation stage.

A20. The customizable probe card of any of paragraphs A13-A19, wherein the respective probe translation stage includes, and optionally is, a manually actuated translation stage.

A21. The customizable probe card of any of paragraphs A9-A20, wherein the respective probe holder of at least one probe assembly of the one or more probe assemblies is directly coupled to the respective probe translation stage of the at least one probe assembly.

A22. The customizable probe card of any of paragraphs A1-A21, wherein the probe repositioning assembly and/or a/the respective probe repositioning mechanism of at least one probe assembly of the one or more probe assemblies includes, and optionally is, a respective probe assembly mounting structure configured to be operatively coupled to the support structure; wherein the respective probe assembly mounting structure is configured to selectively and operatively retain the probe assembly of the one or more probe assemblies at a selected location relative to the support structure and to facilitate selective adjustment of an orientation of the probe assembly relative to the support structure to any of a plurality of distinct selected orientations relative to the support structure, optionally wherein the respective probe assembly mounting structure is configured to selectively and operatively uncouple the probe assembly of the one or more probe assemblies from the support structure to facilitate the selective adjustment of the orientation of the probe assembly relative to the support structure.

A23. The customizable probe card of paragraph A22, wherein the plurality of distinct selected orientations includes, and optionally is, a continuous distribution of distinct orientations.

A24. The customizable probe card of any of paragraphs A22-A23, wherein the respective probe assembly mounting structure is configured to be selectively retained in position relative to the support structure via one or more of a magnetic force, a mechanical force, and a suction force, optionally a suction force produced by applying a vacuum to an interface region between the respective probe assembly mounting structure and the support structure.

A25. The customizable probe card of any of paragraphs A22-A24, further comprising a magnetic plate; wherein the respective probe assembly mounting structure of at least one probe assembly of the one or more probe assemblies is configured to be magnetically coupled to the magnetic plate, optionally selectively magnetically coupled to the magnetic plate.

A26. The customizable probe card of paragraph A25, wherein one or both of the magnetic plate and the respective probe assembly mounting structure includes, and optionally is, one or more of a magnetized material, a ferromagnetic material, and a permanent magnet.

A27. The customizable probe card of any of paragraphs A25-A26, wherein the respective probe assembly mounting structure includes a magnetic plate coupling material that is configured to magnetically couple the probe assembly mounting structure to the magnetic plate.

A28. The customizable probe card of paragraph A27, wherein the magnetic plate coupling material includes, and optionally is, one or more of a magnetized material, a ferromagnetic material, and a permanent magnet.

A29. The customizable probe card of any of paragraphs A25-A28, wherein the magnetic plate is at least substantially fixed relative to the support structure.

A30. The customizable probe card of any of paragraphs A25-A29, wherein the support structure includes, and optionally is, the magnetic plate.

A31. The customizable probe card of any of paragraphs A25-A30, wherein one or both of the magnetic plate and the respective probe assembly mounting structure includes an electromagnet that is configured to be selectively magnetized to selectively retain the respective probe assembly mounting structure in position relative to the magnetic plate.

A32. The customizable probe card of any of paragraphs A25-A31, wherein the respective probe assembly mounting structure is configured to be selectively translated relative to the magnetic plate along a direction at least substantially perpendicular to a/the normal axis while the respective probe assembly mounting structure is operatively magnetically coupled to the magnetic plate.

A33. The customizable probe card of any of paragraphs A25-A32, wherein the one or more probe assemblies includes a plurality of probe assemblies; wherein the magnetic plate is one of a plurality of magnetic plates that are spaced apart from one another; wherein each magnetic plate of the plurality of magnetic plates is at least substantially fixed relative to the support structure; and wherein each respective probe assembly mounting structure of at least two probe assemblies of the plurality of probe assemblies is configured to be magnetically coupled to a respective magnetic plate of the plurality of magnetic plates.

A34. The customizable probe card of any of paragraphs A22-A33, wherein the respective probe assembly mounting structure includes, and optionally is, a/the respective probe translation stage.

A35. The customizable probe card of any of paragraphs A22-A34, wherein the respective probe assembly mounting structure operatively supports a/the respective probe translation stage relative to the support structure.

A36. The customizable probe card of any of paragraphs A22-A35, wherein one or more of the respective probe assembly mounting structure, the support structure, and the magnetic plate includes a gas connector that is configured to be fluidly connected to a gas conduit.

A37. The customizable probe card of paragraph A36, wherein the gas connector includes one or more of a barb, a nipple, a quick release coupling, and a threaded coupling.

A38. The customizable probe card of any of paragraphs A22-A37, wherein the respective probe holder of the at least one probe assembly is operatively coupled to the respective probe assembly mounting structure of the at least one probe assembly at least partially via a magnetic force.

A39. The customizable probe card of paragraph A38, wherein one or both of the respective probe holder and the respective probe assembly mounting structure includes, and optionally is, one or more of a magnetized material, a ferromagnetic material, and a permanent magnet.

A40. The customizable probe card of any of paragraphs A38-A39, wherein one or both of:

(i) the respective probe holder includes a mounting structure coupling material that is configured to magnetically couple the respective probe holder to the respective probe assembly mounting structure; and

(ii) the respective probe assembly mounting structure includes a probe holder coupling material that is configured to magnetically couple the respective probe holder to the respective probe assembly mounting structure.

A41. The customizable probe card of paragraph A40, wherein one or both of the mounting structure coupling material and the probe holder coupling material includes, and optionally is, one or more of a magnetized material, a ferromagnetic material, and a permanent magnet.

A42. The customizable probe card of any of paragraphs A38-A41, wherein the respective probe holder is configured to be selectively translated relative to the respective probe assembly mounting structure along a direction at least substantially parallel to a/the normal axis while the respective probe holder is operatively magnetically coupled to the respective probe assembly mounting structure.

A43. The customizable probe card of any of paragraphs A1-A42, wherein the respective probe holder of at least one probe assembly of the one or more probe assemblies is directly coupled to the support structure.

A44. The customizable probe card of paragraph A43, wherein the respective probe holder includes, and optionally is, a/the respective probe assembly mounting structure.

A45. The customizable probe card of any of paragraphs A1-A44, wherein the customizable probe card is configured to be operatively supported by a probe card holder of a probe system that includes the customizable probe card; and wherein the customizable probe card is configured to be selectively and repeatedly operatively coupled to and uncoupled from the probe card holder.

A46. The customizable probe card of paragraph A45, wherein the support structure includes a mounting structure for selectively and repeatedly operatively coupling the customizable probe card to the probe card holder.

A47. The customizable probe card of paragraph A46, wherein the mounting structure includes one or more of a mechanical fastener, a fastener receiver, a press-fit interface, and a zero insertion force (ZIF) connector.

A48. The customizable probe card of any of paragraphs A1-A47 further comprising an electrical interface configured to transfer electrical signals between the one or more probe assemblies and a component of the probe system exterior to the customizable probe card.

A49. The customizable probe card of paragraph A48, wherein the electrical interface includes one or both of an electrical cable connector and an electrical contact.

A50. The customizable probe card of any of paragraphs A48-A49, wherein a/the mounting structure includes the electrical interface.

A51. The customizable probe card of any of paragraphs A48-A50, wherein at least one probe assembly of the one or more probe assemblies includes the electrical interface.

A52. The customizable probe card of paragraph A51 wherein one or both of at least one probe assembly of the one or more probe assemblies and the respective probe holder thereof includes the electrical interface.

A53. The customizable probe card of any of paragraphs A1-A52, wherein the respective probe of at least one probe assembly of the one or more probe assemblies includes a respective probe body that is operatively coupled to the respective probe holder and a respective probe tip configured to test a respective DUT of the one or more DUTs.

A54. The customizable probe card of paragraph A53, wherein the respective probe body is configured to be selectively and repeatedly operatively coupled to and uncoupled from the respective probe holder.

A55. The customizable probe card of any of paragraphs A53-A54, wherein the respective probe tip is configured to provide a corresponding test signal to the respective DUT and/or to receive a corresponding resultant signal from the respective DUT.

A56. The customizable probe card of paragraph A55, wherein the corresponding test signal includes, and optionally is, one or more of a direct current test signal, an alternating current test signal, an analog test signal, and a digital test signal.

A57. The customizable probe card of any of paragraphs A53-A56, wherein one or both of the probe body and the probe tip includes, and optionally is, a microelectromechanical system (MEMS) device.

A58. The customizable probe card of any of paragraphs A1-A57, wherein the respective probe of each probe assembly of the one or more probe assemblies includes, and optionally is, one or more of a vertical probe, a cantilever probe, and an optical probe.

A59. The customizable probe card of any of paragraphs A1-A58, wherein each DUT of the one or more DUTs includes one or more testing locations; and wherein the respective probe of each probe assembly of the customizable probe card is configured to interface with a respective testing location of the one or more testing locations of the respective DUT to test the respective DUT.

A60. The customizable probe card of paragraph A59, wherein the probe repositioning assembly is configured to align the respective probe of at least one probe assembly of the one or more probe assemblies with the respective testing location, optionally to vertically align the respective probe with the respective testing location and/or to horizontally align the respective probe with the respective testing location.

A61. The customizable probe card of any of paragraphs A59-A60, wherein each DUT of the one or more DUTs includes a single respective testing location.

A62. The customizable probe card of any of paragraphs A59-A60, wherein each DUT of the one or more DUTs includes a plurality of respective testing locations.

A63. The customizable probe card of any of paragraphs A59-A62, wherein each respective testing location of the one or more testing locations of each respective DUT of the one or more DUTs includes, and optionally is, one or more of a contact pad, a solder bump, and an optical coupler.

A64. The customizable probe card of any of paragraphs A59-A63, wherein the respective probe tip is configured to physically contact the respective testing location during operative use of the customizable probe card to test the respective DUT.

A65. The customizable probe card of any of paragraphs A53-A64, wherein the respective probe tip is configured for non-contact testing of the respective DUT.

A66. The customizable probe card of paragraph A65, wherein the respective probe tip is configured to be spaced apart from a/the respective testing location during operative use of the customizable probe card to test the respective DUT.

A67. The customizable probe card of any of paragraphs A1-A66, wherein the customizable probe card has a maximum linear dimension that is one or more of at least 5 centimeters (cm), at least 10 cm, at least 20 cm, at least 30 cm, at least 40 cm, at most 50 cm, at most 35 cm, at most 25 cm, at most 15 cm, and at most 7 cm.

B1. A probe system, comprising:

a chuck with a chuck support surface configured to support a substrate that includes one or more devices under test (DUTs);

a customizable probe card configured to test the one or more DUTs; and

a probe card holder configured to support the customizable probe card relative to the substrate;

wherein the customizable probe card is configured to be selectively and repeatedly operatively coupled to and uncoupled from the probe card holder; and wherein the customizable probe card is the customizable probe card of any of paragraphs A1-A67.

B2. The probe system of paragraph B1, further comprising a chuck translation stage with a chuck translation stage support surface that supports the chuck; wherein the chuck translation stage is configured to operatively translate and/or rotate the chuck relative to the customizable probe card.

B3. The probe system of paragraph B2, wherein the chuck translation stage is configured to move the substrate relative to the customizable probe card to at least partially align the respective probe of at least one probe assembly of the one or more probe assemblies with a corresponding DUT of the one or more DUTs.

B4. The probe system of any of paragraphs B1-B3, further comprising a platen that supports one or both of the probe card holder and the customizable probe card relative to the substrate.

B5. The probe system of paragraph B4, wherein the platen includes, and optionally is, the probe card holder.

B6. The probe system of any of paragraphs B4-B5, wherein the platen supports the customizable probe card such that the support structure is positioned between the platen and the chuck during operative use of the customizable probe card to test the one or more DUTs, optionally while the one or more DUTs are positioned below the customizable probe card.

B7. The probe system of paragraph B6, wherein the customizable probe card is suspended by the platen during operative use of the customizable probe card to test the one or more DUTs.

B8. The probe system of any of paragraphs B4-B7, wherein the probe repositioning assembly includes, and optionally is, a/the respective probe repositioning mechanism of at least one probe assembly of the one or more probe assemblies; and wherein each respective probe repositioning mechanism is operatively coupled to a portion of the support structure that extends below the platen.

B9. The probe system of any of paragraphs B1-B8, further comprising a signal generation and analysis assembly configured to one or both of:

(i) provide a/the corresponding test signal to the customizable probe card; and

(ii) receive a/the corresponding resultant signal from the customizable probe card.

B10. The probe system of any of paragraphs B1-B9, further comprising a controller configured to at least partially control the operation of the probe system.

B11. The probe system of paragraph B10, wherein the controller is configured to transmit a stage control signal to a/the respective probe translation stage of each probe assembly of the one or more probe assemblies.

B12. The probe system of any of paragraphs B10-B11, wherein the controller is a network-connected device that is configured to receive a wireless control signal from a user interface device; and wherein the stage control signal is at least partially based upon the wireless control signal.

B13. The probe system of paragraph B12, wherein the user interface device includes, and optionally is, a device that is configured to provide a user with a user interface for receiving an input corresponding to a desired adjustment of the respective probe translation stage of at least one probe assembly of the one or more probe assemblies.

B14. The probe system of any of paragraphs B10-B13, wherein one or both of the controller and a/the user interface device includes one or more of a computer, a software program, a Web site, a mobile phone, and an Internet-connected device.

B15. The probe system of any of paragraphs B1-B14, further comprising an imaging device configured to generate an optical image of at least a portion of the probe system, optionally wherein the imaging device is configured to receive light along a direction at least substantially parallel to a/the normal axis to generate the optical image.

B16. The probe system of paragraph B15, wherein the imaging device includes one or more of a microscope, a microscope that includes an eyepiece, a microscope that does not include an eyepiece, a camera, a charge-coupled device, an imaging sensor, a solid-state imaging device, a C-MOS imaging device, and a lens.

B17. The probe system of any of paragraphs B15-B16, wherein the imaging device is operatively supported by a corresponding probe assembly, optionally by a/the probe body of the respective probe of the corresponding probe assembly.

B18. The probe system of paragraph B17, wherein the imaging device is operatively coupled to one or both of the respective probe holder of the corresponding probe assembly and the respective probe of the corresponding probe assembly such that at least a portion of the corresponding probe assembly remains one or both of in focus to the imaging device and within a field of view of the imaging device while the corresponding probe assembly is moved relative to the substrate.

B19. The probe system of any of paragraphs B15-B16, when dependent from paragraph B9, wherein the user interface is configured to provide the user with the optical image that is generated by the imaging device.

B20. The probe system of any of paragraphs B1-B19, further comprising:

a gas source configured to generate a pressurized flow of a gas, optionally air; and

a/the gas conduit extending from the gas source to convey the pressurized flow from the gas source; and

wherein a/the respective probe assembly mounting structure of at least one probe assembly of the one or more probe assemblies includes a/the gas connector that is configured to be fluidly connected to the gas conduit to receive the pressurized flow and to convey the pressurized flow to an interface between the respective probe assembly mounting structure and the support structure.

B21. The probe system of any of paragraphs B1-B20, further comprising:

a vacuum source; and

a/the gas conduit extending from the vacuum source;

wherein the vacuum source is configured to pull gas through the gas conduit; and wherein a/the respective probe assembly mounting structure of at least one probe assembly of the one or more probe assemblies includes a/the gas connector that is configured to be fluidly connected to the gas conduit to permit the vacuum source to selectively evacuate air from an/the interface region between the respective probe assembly mounting structure and the support structure to selectively retain the respective probe assembly mounting structure relative to the support structure.

B22. The probe system of any of paragraphs B20-B21, further comprising a valve for selectively regulating a flow of gas through the gas conduit.

B23. The probe system of paragraph B22, wherein the valve is a manually actuated valve.

B24. The probe system of paragraph B22, wherein the valve is a remotely controlled valve, and wherein a/the controller is configured to transmit a valve control signal to the valve to regulate the flow of gas through the gas conduit.

B25. The probe system of any of paragraphs B1-B24, further comprising a repositioning jig configured to facilitate alignment of each respective probe holder at a predetermined orientation relative to the support structure.

B26. The probe system of paragraph B25, wherein the repositioning jig is configured to selectively engage the respective probe assembly mounting structure of at least one probe assembly of the one or more probe assemblies to bring each respective probe assembly mounting structure to the predetermined orientation relative to the support structure.

B27. The probe system of paragraph B26, wherein the repositioning jig includes, and optionally is, one or more of a motorized jig, a manually adjustable jig, a robot, and a template for positioning each probe.

B28. The probe system of any of paragraphs B25-B27, wherein the repositioning jig is configured to assume a configuration that corresponds to a configuration of a/the testing locations of the one or more DUTs.

B29. The probe system of any of paragraphs B1-B28, further comprising an enclosure that at least partially defines an enclosure volume that receives at least a portion of the customizable probe card, optionally that receives at least the support structure of the customizable probe card.

B30. The probe system of paragraph B29, wherein the enclosure is configured to at least partially shield the enclosure volume from the ambient environment that is external to the enclosure.

B31. The probe system of any of paragraphs B29-B30, wherein a/the platen at least partially defines the enclosure volume.

C1. A method of reconfiguring a customizable probe card that includes a support structure, one or more probe assemblies operatively coupled to the support structure and including respective probes, and a probe repositioning assembly configured to facilitate selective adjustment of a relative orientation of the respective probe of at least one probe assembly of the one or more probe assemblies relative to the support structure, the method comprising:

repositioning the respective probe of at least one probe assembly of the one or more probe assemblies;

wherein the repositioning the respective probe includes utilizing the probe repositioning assembly; and wherein the customizable probe card is the customizable probe card of any of paragraphs A1-A67.

C2. The method of paragraph C1, wherein the customizable probe card is the customizable probe card of the probe system of any of paragraphs B1-B31.

C3. The method of any of paragraphs C1-C2, wherein the repositioning the respective probe of the at least one probe assembly includes bringing the respective probe of each probe assembly of the at least one probe assembly to a respective orientation that corresponds to a configuration of a/the one or more testing locations.

C4. The method of any of paragraphs C1-C3, wherein the probe repositioning assembly includes, and optionally is, a/the respective probe repositioning mechanism of at least one probe assembly of the one or more probe assemblies; wherein the respective probe repositioning mechanism of at least one probe assembly of the one or more probe assemblies includes, and optionally is, a/the respective probe translation stage that operatively supports one or both of a/the respective probe holder and the respective probe relative to the support structure; and wherein the repositioning the respective probe of the at least one probe assembly includes repositioning the respective probe with the probe translation stage.

C5. The method of paragraph C4, wherein the repositioning the respective probe with the respective probe translation stage includes one or both of:

(i) translating the respective probe relative to the support structure along one or more linear directions; and

(ii) rotating the respective probe relative to the support structure.

C6. The method of any of paragraphs C4-C5, wherein the repositioning the respective probe with the respective probe translation stage includes controlling the respective probe translation stage at least partially with a/the controller, optionally by transmitting a/the stage control signal from the controller to the respective probe translation stage.

C7. The method of any of paragraphs C1-C6, wherein a/the probe repositioning mechanism of at least one probe assembly of the one or more probe assemblies includes, and optionally is, a/the respective probe assembly mounting structure configured to selectively and operatively couple the probe assembly to the support structure at a selected location on the support structure; and wherein the repositioning the respective probe of the at least one probe assembly includes repositioning the respective probe assembly mounting structure relative to the support structure to reposition the respective probe relative to the support structure, optionally wherein the repositioning the respective probe assembly mounting structure relative to the support structure includes translating the respective probe assembly mounting structure relative to the support structure along a direction at least substantially perpendicular to a/the normal axis.

C8. The method of paragraph C7, wherein the repositioning the respective probe assembly mounting structure includes moving the respective probe assembly mounting structure to one or both of a different location and a different rotational orientation upon the support structure.

C9. The method of paragraph C8, wherein the moving the respective probe assembly mounting structure includes moving the respective probe assembly mounting structure to assume a selected orientation of a continuous distribution of orientations relative to the support structure.

C10. The method of any of paragraphs C8-C9, wherein the repositioning the respective probe assembly mounting structure further includes one or both of:

(i) uncoupling the respective probe assembly mounting structure from the support structure; and

(ii) coupling the respective probe assembly mounting structure to the support structure.

C11. The method of paragraph C10, wherein the respective probe assembly mounting structure is operatively coupled to a/the magnetic plate via a magnetic force; and wherein the uncoupling the respective probe assembly mounting structure from the support structure includes conveying a/the pressurized flow of gas to a/the interface between the probe assembly mounting structure and the magnetic plate to at least partially urge the respective probe assembly mounting structure away from the magnetic plate.

C12. The method of paragraph C11, wherein the uncoupling the respective probe assembly mounting structure includes one or more of:

(i) generating the pressurized flow with a/the gas source;

(ii) conveying the pressurized flow through a/the gas conduit to the respective probe assembly mounting structure to reduce a friction between the respective probe assembly mounting structure and the magnetic plate; and

(iii) regulating the pressurized flow with a/the valve.

C13. The method of paragraph C12, wherein the regulating the pressurized flow with the valve includes transmitting a/the valve control signal from a/the controller to the valve.

C14. The method of any of paragraphs C10-C13, wherein the coupling the respective probe assembly mounting structure to the support structure includes restricting the pressurized flow, optionally with a/the valve.

C15. The method of any of paragraphs C10-C14, wherein the respective probe assembly mounting structure is operatively coupled to a/the magnetic plate via a magnetic force; wherein one or both of the respective probe assembly mounting structure and the magnetic plate includes, and optionally is, a/the electromagnet; and wherein one or both of:

(i) the uncoupling the respective probe assembly mounting structure from the support structure includes selectively demagnetizing the electromagnet to selectively decrease the magnitude of the magnetic force; and

(ii) the coupling the respective probe assembly mounting structure to the support structure includes selectively magnetizing the electromagnet to selectively increase the magnitude of the magnetic force.

C16. The method of paragraph C15, wherein one or both of the selectively demagnetizing the electromagnet and the selectively magnetizing the electromagnet includes transmitting an electromagnet control signal from a/the controller to the electromagnet.

C17. The method of any of paragraphs C8-C16, wherein the respective probe assembly mounting structure is configured to be magnetically coupled to a/the magnetic plate; and wherein the moving the respective probe assembly mounting structure includes moving while the respective probe assembly mounting structure remains operatively magnetically coupled to the magnetic plate.

C18. The method of any of paragraphs C7-C17, wherein the moving the respective probe assembly mounting structure includes utilizing a/the repositioning jig to bring the respective probe assembly mounting structure to one or both of a predetermined location and a predetermined rotational orientation upon the support structure.

C19. The method of paragraph C18, wherein the repositioning jig is a motorized repositioning jig.

C20. The method of any of paragraphs C1-C19, wherein the customizable probe card is configured to be selectively and repeatedly operatively coupled to and uncoupled from one or both of a/the probe card holder and a/the platen of a/the probe system, and wherein the repositioning the respective probe of the at least one probe assembly is performed while the customizable probe card remains one or more of:

(i) operatively coupled to the probe card holder;

(ii) operatively coupled to the platen; and

(iii) operatively installed within the probe system.

C21. The method of any of paragraphs C1-C20, further comprising, with the customizable probe card operatively coupled to the probe card holder, one or both of:

(i) prior to the repositioning the respective probe of the at least one probe assembly, separating the respective probe of the at least one probe assembly of the one or more probe assemblies from a/the corresponding DUT; and

(ii) subsequent to the repositioning the respective probe of the at least one probe assembly, establishing an interface between the respective probe of the at least one probe assembly of the one or more probe assemblies and the corresponding DUT.

C22. The method of paragraph C21, wherein the separating the respective probe includes one or both of removing the respective probe from contact with a/the testing location of the corresponding DUT and increasing a distance between the respective probe and the substrate.

C23. The method of any of paragraphs C21-C22, wherein the establishing the interface includes contacting the respective probe to a/the corresponding testing location.

C24. The method of any of paragraphs C21-C23, wherein the establishing the interface includes positioning the respective probe relative to a/the corresponding testing location to establish a non-contact interface between the respective probe and the corresponding testing location.

C25. The method of any of paragraphs C21-C24, wherein one or both of the separating the respective probe and the establishing the interface includes one or both of:

(i) moving the respective probe of at least one probe assembly of the one or more probe assemblies relative to the substrate with a/the respective probe repositioning mechanism, optionally with a/the respective probe translation stage and/or a/the probe assembly mounting structure; and

(ii) moving the substrate relative to the customizable probe card with a/the chuck translation stage.

C26. The method of any of paragraphs C21-C25, wherein the repositioning the respective probe of the at least one probe assembly includes, with the customizable probe card operatively coupled to the probe card holder and prior to the establishing the interface, translating the probe holder relative to a/the respective probe assembly mounting structure along a direction at least substantially parallel to a/the normal axis.

C27. The method of paragraph C26, wherein the translating the probe holder relative to the respective probe assembly mounting structure is performed while the respective probe holder is operatively and magnetically coupled to the respective probe assembly mounting structure.

C28. The method of any of paragraphs C1-C27, wherein the customizable probe card is configured to be selectively and repeatedly operatively coupled to and uncoupled from a/the probe card holder of a/the probe system, and wherein the method further comprises, prior to the repositioning the respective probe of the at least one probe assembly, uncoupling the customizable probe card from the probe card holder.

C29. The method of any of paragraphs C1-C28, wherein the repositioning the respective probe of the at least one probe assembly includes bringing the customizable probe card to a first probe configuration for testing one or more DUTs in a first DUT configuration, and wherein the method further comprises repeating the repositioning the respective probe of the at least one probe assembly to bring the customizable probe card to a second probe configuration for testing one or more DUTs in a second DUT configuration that is different than the first DUT configuration.

D1. The use of the customizable probe card of any of paragraphs A1-A67 with the method of any of paragraphs C1-C29.

E1. The use of the method of any of paragraphs C1-C29 with the customizable probe card of any of paragraphs A1-A67

F1. The use of the probe system of any of paragraphs B1-B31 with the method of any of paragraphs C1-C29. G1. The use of the method of any of paragraphs C1-C29 with the probe system of any of paragraphs B1-B31.

### INDUSTRIAL APPLICABILITY

The customizable probe cards, probe systems, and methods disclosed herein are applicable to the semiconductor manufacturing and test industries.

It is believed that the disclosure set forth above encompasses multiple distinct inventions with independent utility. While each of these inventions has been disclosed in its preferred form, the specific embodiments thereof as disclosed and illustrated herein are not to be considered in a limiting sense as numerous variations are possible. The subject matter of the inventions includes all novel and non-obvious combinations and subcombinations of the various elements, features, functions and/or properties disclosed herein. Similarly, where the claims recite “a” or “a first” element or the equivalent thereof, such claims should be understood to include incorporation of one or more such elements, neither requiring nor excluding two or more such elements.

It is believed that the following claims particularly point out certain combinations and subcombinations that are directed to one of the disclosed inventions and are novel and non-obvious. Inventions embodied in other combinations and subcombinations of features, functions, elements, and/or properties may be claimed through amendment of the present claims or presentation of new claims in this or a related application. Such amended or new claims, whether they are directed to a different invention or directed to the same invention, whether different, broader, narrower, or equal in scope to the original claims, are also regarded as included within the subject matter of the inventions of the present disclosure.

1. A customizable probe card for testing one or more devices under test (DUTs), the customizable probe card comprising:
a support structure; and
one or more probe assemblies operatively supported by the support structure, wherein each probe assembly of the one or more probe assemblies includes:
(i) a respective probe; and
(ii) a respective probe assembly mounting structure configured to be operatively coupled to the support structure; wherein the respective probe assembly mounting structure is configured to selectively and operatively retain the probe assembly of the one or more probe assemblies at a selected location relative to the support structure and to facilitate selective adjustment of an orientation of the probe assembly relative to the support structure to any of a plurality of distinct selected orientations relative to the support structure.

2. The customizable probe card of claim 1, wherein the plurality of distinct selected orientations includes a continuous distribution of distinct orientations.

3. The customizable probe card of claim 1, wherein the respective probe assembly mounting structure is configured to be selectively retained in position relative to the support structure via one or more of a magnetic force, a mechanical force, and a suction force.

4. The customizable probe card of claim 1, further comprising a magnetic plate; wherein the respective probe assembly mounting structure of at least one probe assembly of the one or more probe assemblies is configured to be magnetically coupled to the magnetic plate.

5. The customizable probe card of claim 4, wherein one or both of the magnetic plate and the respective probe assembly mounting structure includes an electromagnet that is configured to be selectively magnetized to selectively retain the respective probe assembly mounting structure in position relative to the magnetic plate.

6. The customizable probe card of claim 4, wherein one or both of the magnetic plate and the respective probe assembly mounting structure includes a permanent magnet.

7. The customizable probe card of claim 1, wherein each probe assembly of the one or more probe assemblies includes a respective probe holder that supports the respective probe; wherein the respective probe of at least one probe assembly of the one or more probe assemblies includes a respective probe body that is operatively coupled to the respective probe holder and a respective probe tip configured to test a respective DUT of the one or more DUTs; and wherein the respective probe body is configured to be selectively and repeatedly operatively coupled to and uncoupled from the respective probe holder.

8. A probe system, comprising:
a chuck with a chuck support surface configured to support a substrate that includes one or more devices under test (DUTs);
the customizable probe card of claim 1; and
a probe card holder configured to support the customizable probe card relative to the substrate;
wherein the customizable probe card is configured to be selectively and repeatedly operatively coupled to and uncoupled from the probe card holder.

9. The probe system of claim 8, wherein the support structure supports the one or more probe assemblies such that each probe assembly of the one or more probe assemblies is operatively coupled to an upper side of the support structure when the customizable probe card is in operative use to test one or more DUTs positioned below the support structure.

10. The probe system of claim 8, further comprising a platen that supports the customizable probe card relative to the substrate; wherein the platen supports the customizable probe card such that the support structure is positioned between the platen and the chuck during operative use of the customizable probe card to test the one or more DUTs.

11. The probe system of claim 8, further comprising an imaging device configured to generate an optical image of at least a portion of the probe system; wherein the imaging device is operatively supported by a probe body of a respective probe of a corresponding probe assembly of the one or more probe assemblies.

12. The probe system of claim 8, further comprising:
a gas source configured to generate a pressurized flow of a gas; and
a gas conduit extending from the gas source to convey the pressurized flow from the gas source; and
wherein one or both of the respective probe assembly mounting structure and the support structure includes a gas connector that is configured to be fluidly connected to the gas conduit and to convey the pressurized flow to an interface between the respective probe assembly mounting structure and the support structure.

13. The probe system of claim 11, further comprising a valve for selectively regulating a flow of gas through the gas conduit; wherein the valve is a remotely controlled valve; and wherein the probe system further comprises a controller that is configured to transmit a valve control signal to the valve to regulate the flow of gas through the gas conduit.

14. The probe system of claim 8, further comprising a repositioning jig configured to facilitate alignment of each respective probe holder at a predetermined orientation relative to the support structure; wherein the repositioning jig is configured to selectively engage the respective probe assembly mounting structure of at least one probe assembly of the one or more probe assemblies to bring each respective probe assembly mounting structure to the predetermined orientation relative to the support structure.

15. A method of reconfiguring the customizable probe card of the probe system of claim 8, the method comprising:
repositioning the respective probe of at least one probe assembly of the one or more probe assemblies;
wherein the repositioning the respective probe includes repositioning the respective probe assembly mounting structure of at least one probe assembly of the one or more probe assemblies relative to the support structure; and wherein the repositioning the respective probe assembly mounting structure includes one or more of:
(i) uncoupling the respective probe assembly mounting structure from the support structure;
(ii) moving the respective probe assembly mounting structure to one or both of a different location and a different rotational orientation upon the support structure; and
(iii) coupling the respective probe assembly mounting structure to the support structure.

16. The method of claim 15, wherein the moving the respective probe assembly mounting structure includes moving the respective probe assembly mounting structure to assume a selected orientation of a continuous distribution of orientations relative to the support structure.

17. The method of claim 15, wherein the customizable probe card further comprises a magnetic plate; wherein the respective probe assembly mounting structure of at least one probe assembly of the one or more probe assemblies is configured to be selectively magnetically coupled to the magnetic plate; wherein the probe system further comprises:
a gas source configured to generate a pressurized flow of a gas; and
a gas conduit extending from the gas source to convey the pressurized flow from the gas source; and
wherein the uncoupling the respective probe assembly mounting structure includes:
(i) generating the pressurized flow with the gas source; and
(ii) conveying the pressurized flow through the gas conduit to the respective probe assembly mounting structure to reduce a friction between the respective probe assembly mounting structure and the magnetic plate.

18. The method of claim 15, wherein the customizable probe card further comprises a magnetic plate; wherein the respective probe assembly mounting structure of at least one probe assembly of the one or more probe assemblies is configured to be selectively magnetically coupled to the magnetic plate; wherein one or both of the magnetic plate and the respective probe assembly mounting structure includes an electromagnet that is configured to be selectively magnetized to selectively retain the respective probe assembly mounting structure in position relative to the magnetic plate; and wherein the uncoupling the respective probe assembly mounting structure includes selectively demagnetizing the electromagnet to selectively decrease the magnitude of the magnetic force.

19. The method of claim 15, wherein the customizable probe card further comprises a magnetic plate; wherein the respective probe assembly mounting structure of at least one probe assembly of the one or more probe assemblies is configured to be magnetically coupled to the magnetic plate; and wherein the moving the respective probe assembly mounting structure includes moving while the respective probe assembly mounting structure remains magnetically coupled to the magnetic plate.

20. A probe system, comprising:
a chuck with a chuck support surface configured to support a substrate that includes one or more devices under test (DUTs);
a customizable probe card configured to test the one or more DUTs, wherein the customizable probe card comprises:
(i) a support structure;
(ii) one or more probe assemblies supported by the support structure, wherein each probe assembly of the one or more probe assemblies includes a respective probe; and
(iii) one or more probe translation stages, wherein each probe translation stage of the one or more probe translation stages is configured to facilitate selective adjustment of an orientation of the respective probe of at least one probe assembly of the one or more probe assemblies relative to the support structure; and
a platen that supports the customizable probe card relative to the substrate;
wherein the platen supports the customizable probe card such that the support structure is positioned between the platen and the chuck during operative use of the customizable probe card to test the one or more DUTs.

21. The probe system of claim 20, wherein each probe assembly of the one or more probe assemblies includes a respective probe translation stage of the one or more probe translation stages; and wherein the respective probe translation stage of at least one probe assembly of the one or more probe assemblies is configured to one or both of:
(i) translate the respective probe relative to the support structure along one or more linear dimensions; and
(ii) rotate the respective probe relative to the support structure.

22. The probe system of claim 21, wherein the respective probe translation stage includes a motorized translation stage; wherein the probe system further comprises a controller configured to transmit a stage control signal to the respective probe translation stage of each probe assembly of the one or more probe assemblies.

23. The probe system of claim 22, wherein the controller is a network-connected device that is configured to receive a wireless control signal from a user interface device; wherein the user interface device includes a device that is configured to provide a user with a user interface for receiving an input corresponding to a desired adjustment of the respective probe translation stage of at least one probe assembly of the one or more probe assemblies; and wherein the stage control signal is at least partially based upon the wireless control signal.

24. The probe system of claim 20, further comprising an imaging device configured to generate an optical image of at least a portion of the probe system;
wherein the imaging device is operatively supported by a probe body of a respective probe of a corresponding probe assembly of the one or more probe assemblies.

25. A method of reconfiguring the customizable probe card of the probe system of claim 20, wherein each probe assembly of the one or more probe assemblies includes a respective probe translation stage of the one or more probe translation stages; the method comprising:
repositioning, with the respective probe translation stage, the respective probe of at least one probe assembly of the one or more probe assemblies; and
wherein the repositioning the respective probe with the respective probe translation stage includes controlling the respective probe translation stage by transmitting a stage control signal from a controller of the probe system to the respective probe translation stage.
